(19) United States
(12) Patent Application Publication
(10) Pub. No.: US 2026/0247597 A1
(43) Pub. Date: Aug. 20, 2026

(54) SEMICONDUCTOR DEVICE INCLUDING MEMORY STRUCTURE AND METHOD FOR MANUFACTURING THE SAME

(71) Applicant: NANYA TECHNOLOGY CORPORATION, NEW TAIPEI CITY (TW)

(72) Inventors: SHIH-FAN KUAN, Taoyuan City (TW); WEI-CHEN PAN, New Taipei City (TW); YU-TING LIN, New Taipei City (TW); HUEI-RU LIN, Toufen City (TW)

(21) Appl. No.: 19/411,436

(22) Filed: Dec. 8, 2025

Related U.S. Application Data
(63) Continuation of application No. 17/973,202, filed on Oct. 25, 2022.

(51) Int. Cl. H10B 12/00; G11C 5/06

(52) U.S. Cl. CPC H10B 12/00; G11C 5/063

(57) ABSTRACT

A semiconductor device and a method of manufacturing the same are provided. The semiconductor device includes a substrate, a plurality of capacitors, and a first supporting layer. The plurality of capacitors are disposed on the substrate. Each of the capacitors extends along a first direction. Each of the plurality of capacitors includes a first capacitor electrode, a second capacitor electrode, and a capacitor dielectric separating the first capacitor electrode from the second capacitor electrode. The first supporting layer is disposed on the substrate. The first supporting layer extends along a second direction different from the first direction. The capacitor dielectric includes a first surface and a second surface which are disposed on two opposite sides along the first direction. The second surface is exposed by the first capacitor electrode. The first supporting layer is disposed between the first surface and the second surface of the capacitor dielectric.

### CROSS-REFERENCE TO RELATED APPLICATION

This application is a continuation application of U.S. Non-Provisional application Ser. No. 17/973,202 filed Oct. 25, 2022, which is incorporated herein by reference in its entirety.

### TECHNICAL FIELD

The present disclosure relates to a semiconductor device and a method of manufacturing the same, and in particularly to a semiconductor device including a three-dimensional memory structure.

### DISCUSSION OF THE BACKGROUND

With the rapid growth of the electronics industry, the development of integrated circuits (ICs) has achieved high performance and miniaturization. Technological advances in IC materials and design have produced generations of ICs where each generation has smaller and more complex circuits than the previous generation.

A Dynamic Random Access Memory (DRAM) device is a type of random access memory that stores each bit of data in a separate capacitor within an integrated circuit. Typically, a DRAM is arranged in a square array of one capacitor and transistor per cell. A vertical transistor has been developed for the 4F² DRAM cell, in which F represents the photolithographic minimum feature width or critical dimension (CD). However, recently, DRAM manufacturers are facing significant challenges in minimizing memory cell area as word line spacing continues to be reduced.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a plurality of capacitors, and a first supporting layer. The plurality of capacitors are disposed on the substrate. Each of the capacitors extends along a first direction. Each of the plurality of capacitors includes a first capacitor electrode, a second capacitor electrode, and a capacitor dielectric separating the first capacitor electrode from the second capacitor electrode. The first supporting layer is disposed on the substrate. The first supporting layer extends along a second direction different from the first direction. The capacitor dielectric includes a first surface and a second surface which are disposed on two opposite sides along the first direction. The second surface is exposed by the first capacitor electrode. The first supporting layer is disposed between the first surface and the second surface of the capacitor dielectric.

Another aspect of the present disclosure provides a semiconductor device. The semiconductor device includes a substrate and a plurality of capacitors. The substrate has an upper surface. The plurality of capacitors are disposed on the upper surface of the substrate. The plurality of capacitors are arranged along a plane that is substantially perpendicular to the upper surface of the substrate.

Another aspect of the present disclosure provides a method for manufacturing a semiconductor device. The method includes: providing a substrate; forming a plurality of isolation layers and a plurality of first conductive layers over the substrate, wherein the plurality of isolation layers and the plurality of first conductive layers are stacked alternatively; patterning the plurality of isolation layers and the plurality of first conductive layers to form a plurality of island structures; removing a first portion of the plurality of isolation layers to expose the plurality of first conductive layers; forming a capacitor dielectric to cover the plurality of first conductive layers; and forming a second conductive layers to cover the capacitor dielectric.

The embodiments of the present disclosure provide a semiconductor device. The semiconductor device may define a three-dimensional memory device. For example, the capacitors may be arranged along a plane which is substantially the capacitors may be arranged along a plane which is substantially perpendicular to the upper surface of the substrate, which reduces the overall thickness of the semiconductor device. Further, the semiconductor device may include supporting layers. The supporting layers may be configured to reinforce the intermediate structure during manufacturing processes. The supporting layers may be configured to increase the length of the first capacitor electrode of the capacitor and prevent the first capacitor electrode from collapsing, which may increase the number of capacitors.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a perspective view of a semiconductor device, in accordance with some embodiments of the present disclosure.

FIG. 1B is a cross-section along line A-A′ of the semiconductor device as shown in FIG. 1A, in accordance with some embodiments of the present disclosure.

FIG. 1C is a cross-section along line B-B′ of the semiconductor device as shown in FIG. 1A, in accordance with some embodiments of the present disclosure.

FIG. 1D is a cross-section along line C-C′ of the semiconductor device as shown in FIG. 1A, in accordance with some embodiments of the present disclosure.

FIG. 1E is a cross-section along line D-D′ of the semiconductor device as shown in FIG. 1A, in accordance with some embodiments of the present disclosure.

FIG. 2 is a cross-section of a semiconductor device, in accordance with some embodiments of the present disclosure.

FIG. 3 is a flowchart illustrating a method of manufacturing a semiconductor device, in accordance with some embodiments of the present disclosure

FIG. 4A, FIG. 4B, FIG. 4C, FIG. 4D and FIG. 4E illustrate one or more stages of an exemplary method for manufacturing a semiconductor device according to some embodiments of the present disclosure.

FIG. 5A, FIG. 5B, FIG. 5C, FIG. 5D and FIG. 5E illustrate one or more stages of an exemplary method for manufacturing a semiconductor device according to some embodiments of the present disclosure.

FIG. 6A, FIG. 6B, FIG. 6C, FIG. 6D and FIG. 6E illustrate one or more stages of an exemplary method for manufacturing a semiconductor device according to some embodiments of the present disclosure.

FIG. 7A, FIG. 7B, FIG. 7C, FIG. 7D and FIG. 7E illustrate one or more stages of an exemplary method for manufacturing a semiconductor device according to some embodiments of the present disclosure.

FIG. 8A, FIG. 8B, FIG. 8C, FIG. 8D and FIG. 8E illustrate one or more stages of an exemplary method for manufacturing a semiconductor device according to some embodiments of the present disclosure.

FIG. 9A, FIG. 9B, FIG. 9C, FIG. 9D and FIG. 9E illustrate one or more stages of an exemplary method for manufacturing a semiconductor device according to some embodiments of the present disclosure.

FIG. 10A, FIG. 10B, FIG. 10C, FIG. 10D and FIG. 10E illustrate one or more stages of an exemplary method for manufacturing a semiconductor device according to some embodiments of the present disclosure.

FIG. 11A, FIG. 11B, FIG. 11C, FIG. 11D and FIG. 11E illustrate one or more stages of an exemplary method for manufacturing a semiconductor device according to some embodiments of the present disclosure.

FIG. 12A, FIG. 12B, FIG. 12C, FIG. 12D and FIG. 12E illustrate one or more stages of an exemplary method for manufacturing a semiconductor device according to some embodiments of the present disclosure.

FIG. 13A, FIG. 13B, FIG. 13C, FIG. 13D and FIG. 13E illustrate one or more stages of an exemplary method for manufacturing a semiconductor device according to some embodiments of the present disclosure.

FIG. 14A, FIG. 14B, FIG. 14C, FIG. 14D and FIG. 14E illustrate one or more stages of an exemplary method for manufacturing a semiconductor device according to some embodiments of the present disclosure.

FIG. 15A, FIG. 15B, FIG. 15C, FIG. 15D and FIG. 15E illustrate one or more stages of an exemplary method for manufacturing a semiconductor device according to some embodiments of the present disclosure.

FIG. 16A, FIG. 16B, FIG. 16C, FIG. 16D and FIG. 16E illustrate one or more stages of an exemplary method for manufacturing a semiconductor device according to some embodiments of the present disclosure.

FIG. 17A, FIG. 17B, FIG. 17C, FIG. 17D and FIG. 17E illustrate one or more stages of an exemplary method for manufacturing a semiconductor device according to some embodiments of the present disclosure.

FIG. 18A, FIG. 18B, FIG. 18C, FIG. 18D and FIG. 18E illustrate one or more stages of an exemplary method for manufacturing a semiconductor device according to some embodiments of the present disclosure.

FIG. 19A, FIG. 19B, FIG. 19C, FIG. 19D and FIG. 19E illustrate one or more stages of an exemplary method for manufacturing a semiconductor device according to some embodiments of the present disclosure.

FIG. 20A, FIG. 20B, FIG. 20C, FIG. 20D and FIG. 20E illustrate one or more stages of an exemplary method for manufacturing a semiconductor device according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that when an element is referred to as being “connected to” or “coupled to” another element, the initial element may be directly connected to, or coupled to, another element, or to other intervening elements.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure employed refers to variation in the numerical quantity that may occur, for example, through typical measuring and liquid handling procedures used for making concentrates or solutions. Furthermore, variation may occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

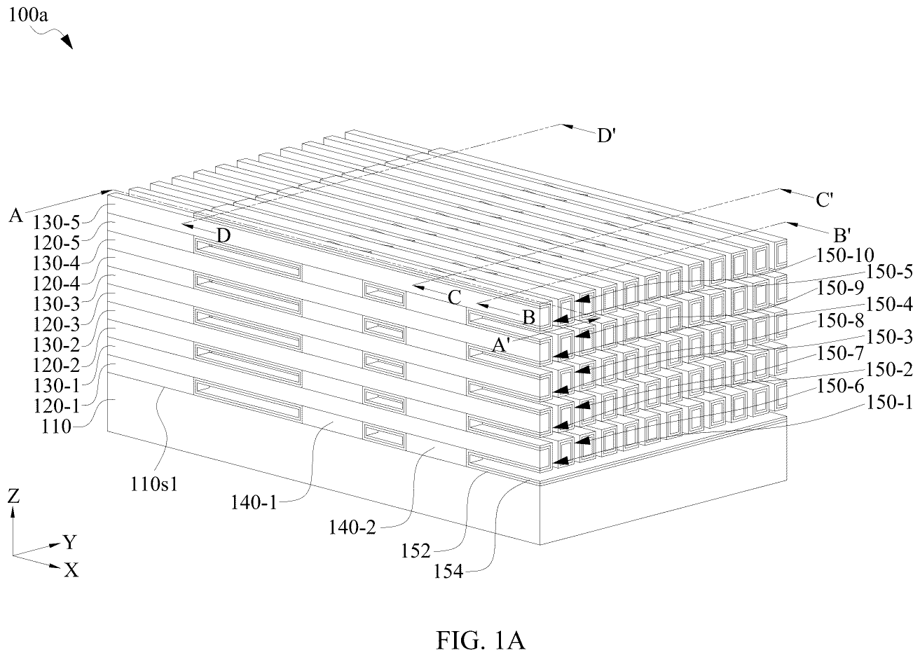

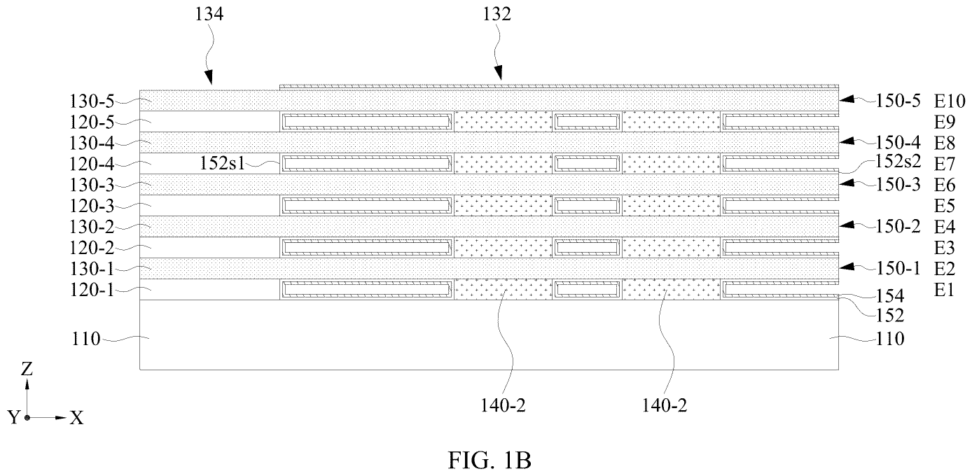

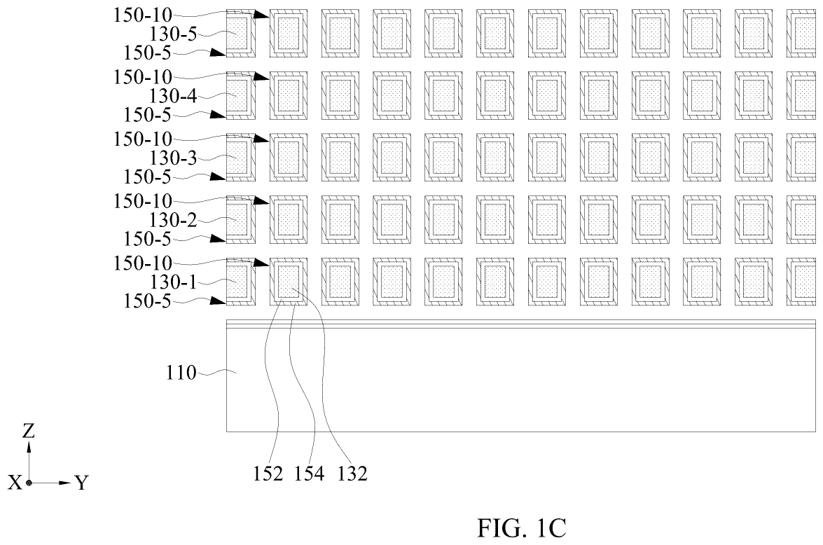

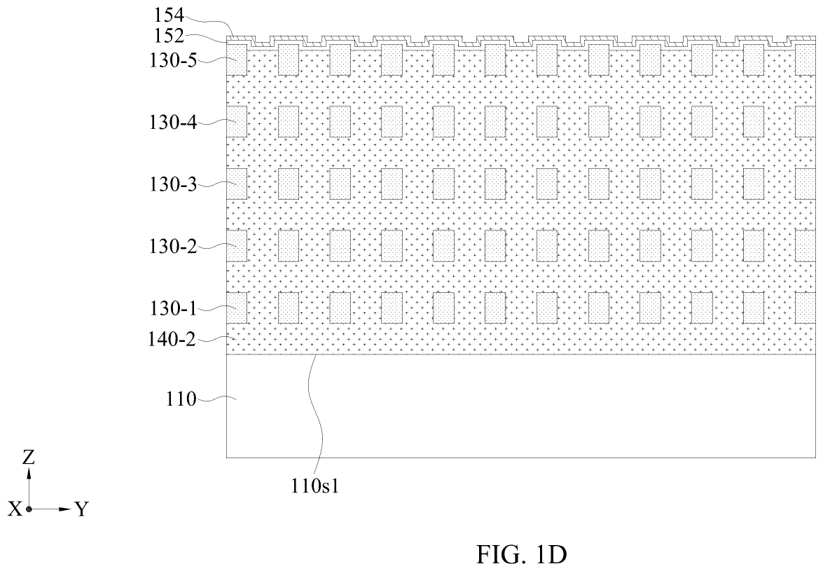

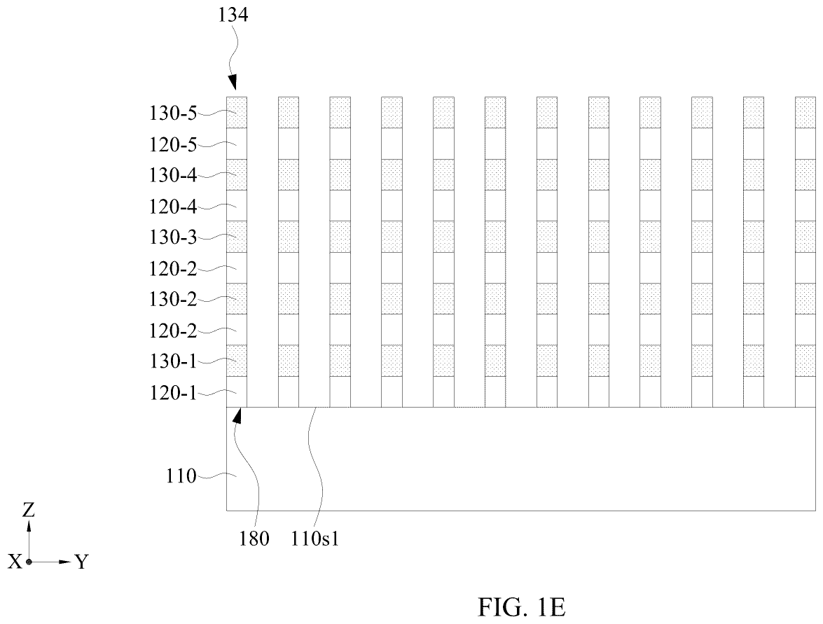

Referring to FIG. 1A, FIG. 1A is a perspective view of a semiconductor device 100a, in accordance with some embodiments of the present disclosure. The semiconductor device 100a may be included in a memory device. The memory device may include, for example, a dynamic random access memory (DRAM) device, a one-time programming (OTP) memory device, a static random access memory (SRAM) device, or other suitable memory devices.

As shown in FIG. 1A, the semiconductor device 100a may include a substrate 110, isolation layers 120-1, 120-2, 120-3, 120-4, and 120-5, conductive layers 130-1, 130-2, 130-3, 130-4, and 130-5, and supporting layers 140-1 and 140-2, as well as capacitors 150-1, 150-2, 150-3, 150-4, 150-5, 150-6, 150-7, 150-8, 150-9, and 150-10.

The substrate 110 may be a semiconductor substrate, such as a bulk semiconductor, a semiconductor-on-insulator (SOI) substrate, or the like. The substrate 110 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may include a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 110 may have a multilayer structure, or the substrate 110 may include a multilayer compound semiconductor structure. The substrate 110 may have a surface 110s1 (or an upper surface). The normal direction of the surface 110s1 may substantially parallel to the Z direction.

In some embodiments, the isolation layer 120-1 may be disposed on the surface 110s1 of the substrate 110. In some embodiments, the isolation layer 120-1 may be in contact with the substrate 110. The isolation layer 120-2 may be disposed on the isolation layer 120-1. In some embodiments, the isolation layer 120-2 may be spaced apart from the isolation layer 120-1 by the conductive layer 130-1. The isolation layer 120-3 may be disposed on the isolation layer 120-2. In some embodiments, the isolation layer 120-3 may be spaced apart from the isolation layer 120-2 by the conductive layer 130-2. The isolation layer 120-4 may be disposed on the isolation layer 120-3. In some embodiments, the isolation layer 120-4 may be spaced apart from the isolation layer 120-3 by the conductive layer 130-3. The isolation layer 120-5 may be disposed on the isolation layer 120-4. In some embodiments, the isolation layer 120-5 may be spaced apart from the isolation layer 120-4 by the conductive layer 130-4. In some embodiments, the isolation layers 120-1, 120-2, 120-3, 120-4, and 120-5 may be stacked along the Z direction. In some embodiments, the isolation layers 120-1, 120-2, 120-3, 120-4, and 120-5 may be located at different horizontal levels. Each of the isolation layers 120-1, 120-2, 120-3, 120-4, and 120-5 may include a dielectric material, such as silicon oxide (SiOₓ), silicon nitride (SiₓN_{y}), silicon oxynitride (SiON), or other suitable materials.

In some embodiments, the conductive layer 130-1 may be disposed on the surface 110s1 of the substrate 110. In some embodiments, the conductive layer 130-1 may be disposed on the isolation layer 120-1. In some embodiments, the conductive layer 130-1 may be in contact with the isolation layer 120-1. In some embodiments, the conductive layer 130-2 may be disposed on the conductive layer 130-1. In some embodiments, the conductive layer 130-2 may be disposed on the isolation layer 120-2. In some embodiments, the conductive layer 130-3 may be disposed on the conductive layer 130-2. In some embodiments, the conductive layer 130-3 may be disposed on the isolation layer 120-3. In some embodiments, the conductive layer 130-4 may be disposed on the conductive layer 130-3. In some embodiments, the conductive layer 130-4 may be disposed on the isolation layer 120-4. In some embodiments, the conductive layer 130-5 may be disposed on the isolation layer 120-5. In some embodiments, the conductive layers 130-1, 130-2, 130-3, 130-4, and 130-5 may be stacked along the Z direction. In some embodiments, each of the conductive layers 130-1, 130-2, 130-3, 130-4, and 130-5 may extend along the X direction. In some embodiments, the conductive layers 130-1, 130-2, 130-3, 130-4, and 130-5 may be located at different horizontal levels. In some embodiments, each of the conductive layers 130-1, 130-2, 130-3, 130-4, and 130-5 may include conductive materials, such as tungsten (W), copper (Cu), aluminum (Al), tantalum (Ta), molybdenum (Mo), tantalum nitride (TaN), titanium, titanium nitride (TiN), the like, and/or a combination thereof.

In some embodiments, each of the supporting layers 140-1 and 140-2 may extend along the Y direction. In some embodiments, each of the supporting layers 140-1 and 140-2 may be configured to support the capacitors 150-1, 150-2, 150-3, 150-4, 150-5, 150-6, 150-7, 150-8, 150-9, and 150-10. In some embodiments, each of the supporting layers 140-1 and 140-2 may assist in increasing the length, along the X direction, of the capacitors 150-1, 150-2, 150-3, 150-4, 150-5, 150-6, 150-7, 150-8, 150-9, and 150-10. In some embodiments, the supporting layers 140-1 and 140-2 may be arranged along the X direction. In some embodiments, each of the supporting layers 140-1 and 140-2 may continuously extend across, for example, the capacitors 150-1 and 150-6. In some embodiments, the supporting layer 140-1 may be spaced apart from the supporting layer 140-2 by a capacitor dielectric 152. In some embodiments, the supporting layer 140-1 may be spaced apart from the supporting layer 140-2 by a conductive layer 154. In some embodiments, the supporting layer 140-1 may be disposed between, for example, the conductive layers 130-2 and 130-3. In some embodiments, the material of the supporting layers 140-1 and 140-2 may be different from that of the isolation layers 120-1, 120-2, 120-3, 120-4, and 120-5. In some embodiments, each of the supporting layers 140-1 and 140-2 may include silicon nitride (SiₓN_{y}), silicon oxide (SiOₓ), silicon oxynitride (SiON), or other suitable materials.

In some embodiments, the capacitors 150-1, 150-2, 150-3, 150-4, 150-5, 150-6, 150-7, 150-8, 150-9, and 150-10 may be arranged along the YZ plane. In some embodiments, the capacitors 150-1, 150-2, 150-3, 150-4, and 150-5 may be stacked along the Z direction. In some embodiments, the capacitors 150-1, 150-2, 150-3, 150-4, and 150-5 may be located at different horizontal levels. In some embodiments, the capacitors 150-1, 150-2, 150-3, 150-4, 150-5, 150-6, 150-7, 150-8, 150-9, and 150-10 may extend along the X direction. In some embodiments, the capacitor 150-1 may be disposed on the substrate 110. In some embodiments, the capacitor 150-2 may be disposed on the capacitor 150-1. In some embodiments, the capacitor 150-3 may be disposed on the capacitor 150-2. In some embodiments, the capacitor 150-4 may be disposed on the capacitor 150-3. In some embodiments, the capacitor 150-5 may be disposed on the capacitor 150-4. In some embodiments, the capacitors 150-1 and 150-6 may be arranged along the Y direction.

In some embodiments, each of the capacitors 150-1, 150-2, 150-3, 150-4, 150-5, 150-6, 150-7, 150-8, 150-9, and 150-10 may include a first capacitor electrode, a capacitor dielectric, and a second capacitor electrode. In some embodiments, each of the conductive layers 130-1, 130-2, 130-3, 130-4, and 130-5 may serve as the first capacitor electrode. In some embodiments, the capacitor dielectric 152 may serve as the capacitor dielectric. In some embodiments, the conductive layer 154 may serve as the second capacitor electrode.

In some embodiments, the capacitor dielectric 152 may surround or enclose the conductive layers 130-1, 130-2, 130-3, 130-4, and 130-5. In some embodiments, the capacitor dielectric 152 may have a ring-shaped profile in a cross-sectional view. In some embodiments, the capacitor dielectric 152 may be in contact with the supporting layers 140-1 and 140-2. In some embodiments, the capacitor dielectric 152 may extend along the X direction. The capacitor dielectric 152 may include a high-k material. The high-k material may include hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. Other suitable materials are within the contemplated scope of this disclosure.

In some embodiments, the conductive layer 154 may surround or enclose the capacitor dielectric 152. In some embodiments, the conductive layer 154 may surround or enclose the conductive layers 130-1, 130-2, 130-3, 130-4, and 130-5. In some embodiments, the conductive layer 154 may be spaced apart from the conductive layers 130-1, 130-2, 130-3, 130-4, and 130-5 by the capacitor dielectric 152. In some embodiments, the conductive layer 154 may have a ring-shaped profile in a cross-sectional view. In some embodiments, the conductive layer 154 may extend along the X direction. In some embodiments, the material of the conductive layer 154 may be the same as that of the conductive layers 130-1, 130-2, 130-3, 130-4, and 130-5. In some embodiments, the conductive layer 154 may include conductive materials, such as tungsten (W), copper (Cu), aluminum (Al), tantalum (Ta), molybdenum (Mo), tantalum nitride (TaN), titanium, titanium nitride (TiN), the like, and/or a combination thereof.

Referring to FIG. 1B, FIG. 1B is a cross-section along line A-A′ of the semiconductor device 100a as shown in FIG. 1A, in accordance with some embodiments of the present disclosure.

In some embodiments, the isolation layer 120-1, the conductive layer 130-1, the isolation layer 120-2, the conductive layer 130-2, the isolation layer 120-3, the conductive layer 130-3, the isolation layer 120-4, the conductive layer 130-4, the isolation layer 120-5, and the conductive layer 130-5 may be located at horizontal levels E1, E2, E3, E4, E5, E6, E7, E8, E9, and E10, respectively.

The capacitor dielectric 152 may have a surface 152s1 and a surface 152s2. The surfaces 152s1 and 152s2 may be located on two opposite sides along the X direction. The surface 152s1 of the capacitor dielectric may be exposed from the conductive layer 130-1, 130-2, 130-3, 130-4, and 130-5. The surface 152s1 of the capacitor dielectric may be exposed from the conductive layer 154. In some embodiments, the supporting layer 140-1 may be disposed between the surfaces 152s1 and 152s2 of the capacitor dielectric 152. In some embodiments, the supporting layer 140-2 may be disposed between the surfaces 152s1 and 152s2 of the capacitor dielectric 152. In some embodiments, the supporting layer 140-1 may be disposed between two opposite lateral surface of the conductive layer 152.

In some embodiments, each of the isolation layers 120-1, 120-2, 120-3, 120-4, and 120-5 may be in contact with the capacitor dielectric 152. In some embodiments, each of the isolation layers 120-1, 120-2, 120-3, 120-4, and 120-5 may be spaced apart from the conductive layer 154 by the capacitor dielectric 152.

In some embodiments, each of the conductive layers 130-1, 130-2, 130-3, 130-4, and 130-5 may have a portion 132 and a portion 134. In some embodiments, the portions 132 and 134 are monolithic. In some embodiments, the portion 132 may serve as the first capacitor electrode of the capacitors 150-1, 150-2, 150-3, 150-4, 150-5, 150-6, 150-7, 150-8, 150-9, and/or 150-10. In some embodiments, the portion 134 may serve as an interconnection trace between the capacitors 150-1, 150-2, 150-3, 150-4, 150-5, 150-6, 150-7, 150-8, 150-9, or 150-10 and a transistor (not shown in this figure).

Referring to FIG. 1C, FIG. 1C is a cross-section along line B-B′ of the semiconductor device 100a as shown in FIG. 1A, in accordance with some embodiments of the present disclosure.

In some embodiments, each of the conductive layers 130-1, 130-2, 130-3, 130-4, and 130-5 may have a rectangular profile or other suitable profiles. In some embodiments, the capacitor dielectric 152 may completely surround or enclose the conductive layers 130-1, 130-2, 130-3, 130-4, and 130-5. In some embodiments, the conductive layer 154 may completely surround or enclose the capacitor dielectric 152.

Referring to FIG. 1D, FIG. 1D is a cross-section along line C-C′ of the semiconductor device 100a as shown in FIG. 1A, in accordance with some embodiments of the present disclosure.

In some embodiments, the supporting layer 140-2 (or 140-1) may be in contact with the conductive layers 130-1, 130-2, 130-3, 130-4, and 130-5. In some embodiments, the supporting layer 140-2 (or 140-1) may be connected to the conductive layers 130-1, 130-2, 130-3, 130-4, and 130-5. In some embodiments, the supporting layer 140-2 (or 140-1) may be in contact with the surface 110s1 of the substrate 110.

Referring to FIG. 1E, FIG. 1E is a cross-section along line D-D′ of the semiconductor device 100a as shown in FIG. 1A, in accordance with some embodiments of the present disclosure.

In some embodiments, the semiconductor device 100a may include a plurality of island structures 180. Each of the island structures 180 may include the isolation layers 120-1, 120-2, 120-3, 120-4, and 120-5 as well as the conductive layers 130-1, 130-2, 130-3, 130-4, and 130-5. Each of the island structures 180 may extend along the X direction. In some embodiments, portions 134 of each of the conductive layers 130-1, 130-2, 130-3, 130-4, and 130-5 may be spaced apart from each other by the isolation layers 120-1, 120-2, 120-3, 120-4, and 120-5.

The embodiments of the present disclosure provide a semiconductor device. The semiconductor device may define a three-dimensional memory device. For example, the capacitors may be arranged along a plane which is substantially perpendicular to the upper surface of the substrate, which reduces the overall thickness of the semiconductor device. Further, the semiconductor device may include supporting layers. The supporting layers may be configured to reinforce the intermediate structure during manufacturing processes. The supporting layers may be configured to increase the length of the first capacitor electrode of the capacitor and prevent the first capacitor electrode from collapsing, which may increase the number of capacitors.

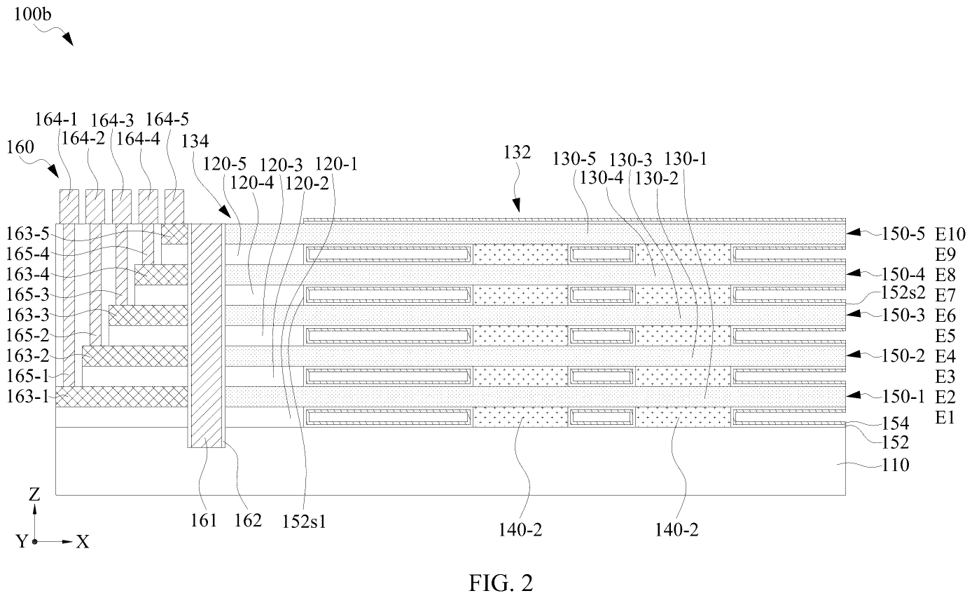

FIG. 2 is a cross-section of a semiconductor device 100b, in accordance with some embodiments of the present disclosure.

The semiconductor device 100b may further include transistor(s) 160. In some embodiments, the transistor 160 may be include a word line 161, a gate dielectric 162, a channel layer 163-1, 163-2, 163-3, 163-4, or 163-5, and a bit line 164-1, 164-2, 164-3, 164-4, or 164-5.

In some embodiments, the word line 161 may be disposed on the substrate 110. In some embodiments, the word line 161 may be disposed between, for example, the bit line 164-1 and the capacitor 150-1. In some embodiments, the word line 161 may penetrate a portion of the substrate 110. In some embodiments, the word line 161 may extend along the Z direction. In some embodiments, the word line 161 may penetrate the isolation layers 120-1, 120-2, 120-3, 120-4, and 120-5. In some embodiments, the word line 161 may include conductive materials, such as tungsten (W), copper (Cu), aluminum (Al), tantalum (Ta), molybdenum (Mo), tantalum nitride (TaN), titanium, titanium nitride (TiN), the like, and/or a combination thereof.

In some embodiments, the gate dielectric 162 may surround the word line 161. In some embodiments, the gate dielectric 162 may separate the word line 161 from the conductive layers 130-1, 130-2, 130-3, 130-4, and 130-5. In some embodiments, the gate dielectric 162 may separate the word line 161 from the channel layers 163-1, 163-2, 163-3, 163-4, or 163-5. In some embodiments, the gate dielectric 162 may penetrate the conductive layers 130-1, 130-2, 130-3, 130-4, and 130-5. In some embodiments, the gate dielectric 162 may penetrate the isolation layers 120-1, 120-2, 120-3, 120-4, and 120-5. In some embodiments, the gate dielectric 162 may include silicon oxide (SiOₓ), silicon nitride (SiₓN_{y}), silicon oxynitride (SiON), or a combination thereof. In some embodiments, the gate dielectric l62 may include dielectric material(s), such as high-k dielectric material. The high-k dielectric material may have a dielectric constant (k value) exceeding 4. The high-k material may include hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. Other suitable materials are within the contemplated scope of this disclosure.

In some embodiments, each of the channel layers 163-1, 163-2, 163-3, 163-4, or 163-5 may extend along the X direction. In some embodiments, each of the channel layers 163-1, 163-2, 163-3, 163-4, or 163-5 may be located at a horizontal the same as that of the conductive layers 130-1, 130-2, 130-3, 130-4, and 130-5, respectively. In some embodiments, the material of the channel layers 163-1, 163-2, 163-3, 163-4, or 163-5 may be different from that of the conductive layers 130-1, 130-2, 130-3, 130-4, and 130-5. In some embodiments, each of the channel layers 163-1, 163-2, 163-3, 163-4, or 163-5 may include a semiconductor material, such as silicon (Si), germanium (Ge), tin (Sn), antimony (Sb) in a single crystal form, a polycrystalline form, or an amorphous form. In some embodiments, each of the channel layers 163-1, 163-2, 163-3, 163-4, or 163-5 may include a doped region (not shown). The doped region may have an n type or p type dopants doped therein. In some embodiments, p type dopants include boron (B), other group III elements, or any combination thereof. In some embodiments, n type dopants include arsenic (As), phosphorus (P), other group V elements, or any combination thereof.

In other embodiments, each of the channel layers 163-1, 163-2, 163-3, 163-4, or 163-5 may include a metal oxide. The metal oxide may include, but is not limited to, indium oxide; tin oxide; zinc oxide; a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide; a three-component metal oxide such as an In—Ga—Zn-based oxide (also represented as IGZO), an In—Al—Zn-based oxide, an In S based oxide (also represented as ITO), an In—Sn—Zn-based oxide, a Sn—Ga—Zn-based oxide, an Al—Ga—Zn-based oxide, a Sn Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide; and a four-component metal oxide such as an In—Sn—Ga—Zn-based oxide, an In—Hf—Ga Zn-based oxide, an In—Al—Ga—Zn-based oxide, an In—Sn—Al Zn-based oxide, an In—Sn—Hf—Zn-based oxide, or an In—Hf—Al—Zn-based oxide, but the present disclosure is not limited in this regard.

In some embodiments, each of the bit lines 164-1, 164-2, 164-3, 164-4, and 164-5 may be disposed over the isolation layer 120-5. In some embodiments, each of the bit lines 164-1, 164-2, 164-3, 164-4, and 164-5 may extend along the Y direction. In some embodiments, each of the bit lines 164-1, 164-2, 164-3, 164-4, and 164-5 may be arranged along the X direction. In some embodiments, each of the bit lines 164-1, 164-2, 164-3, 164-4, and 164-5 may include conductive materials, such as tungsten (W), copper (Cu), aluminum (Al), tantalum (Ta), molybdenum (Mo), tantalum nitride (TaN), titanium, titanium nitride (TiN), the like, and/or a combination thereof.

The semiconductor device 100b may further include conductive plugs 165-1, 165-2, 165-3, and 165-4. The conductive plugs 165-1, 165-2, 165-3, and 165-4 may include conductive materials, such as tungsten (W), copper (Cu), aluminum (Al), tantalum (Ta), molybdenum (Mo), tantalum nitride (TaN), titanium, titanium nitride (TiN), the like, and/or a combination thereof.

In some embodiments, the bit line 164-1 may be electrically connected to the channel layer 163-1 through the conductive plug 165-1. In some embodiments, the bit line 164-2 may be electrically connected to the channel layer 163-2 through the conductive plug 165-2. In some embodiments, the bit line 164-3 may be electrically connected to the channel layer 163-3 through the conductive plug 165-3. In some embodiments, the bit line 164-4 may be electrically connected to the channel layer 163-4 through the conductive plug 165-4. Each of the conductive plugs 165-1, 165-2, 165-3, and 165-4 may have different heights along the Z direction. For example, the conductive plug 165-1 may have a height different from that of the conductive plug 165-2 along the Z direction.

In some embodiments, the transistor 160 may be electrically connected to the capacitors 150-1, 150-2, 150-3, 150-4, and/or 150-5. In some embodiments, the transistor 160 may be electrically connected to the capacitors 150-1, 150-2, 150-3, 150-4, and/or 150-5 by the portion 134 of the conductive layers 130-1, 130-2, 130-3, 130-4, and 130-5. In some embodiments, the interconnection trace (e.g., 134) may be disposed between the transistor 160 and the capacitors 150-1, 150-2, 150-3, 150-4, and 150-5. In some embodiments, the transistor 160 and the capacitors 150-1, 150-2, 150-3, 150-4, and 150-5 are arranged horizontally. For example, the capacitors 150-1, 150-2, 150-3, 150-4, and 150-5 and the word lines occupy substantially the same height, from horizontal levels E1 to E10.

The embodiments of the present disclosure provide a semiconductor device. The semiconductor device may define a three-dimensional memory device. For example, the capacitors and the word lines may be located within a predetermined height, which reduces the overall thickness of the semiconductor device. Further, the semiconductor device may include supporting layers. The supporting layers may be configured to reinforce the intermediate structure during manufacturing processes. The supporting layers may be configured to increase the length of the first capacitor electrode of the capacitor and prevent the first capacitor electrode from collapsing, which may increase the number of capacitors.

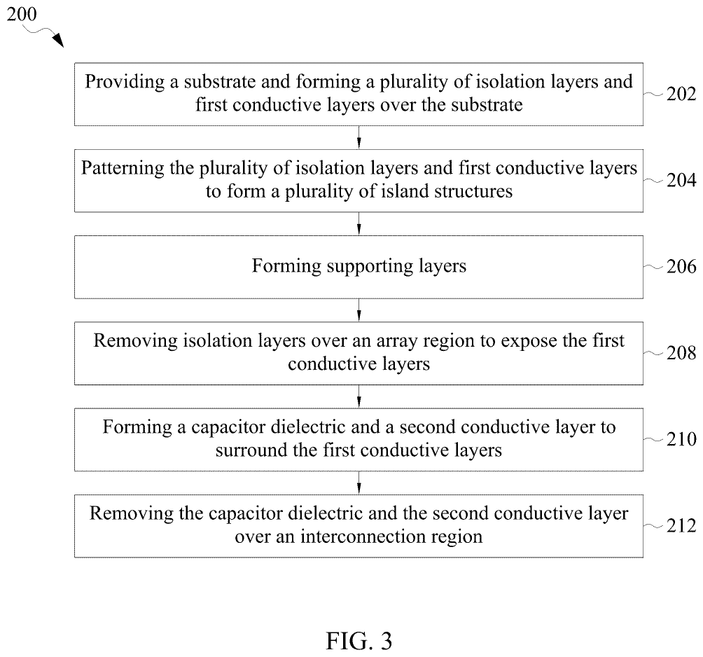

FIG. 3 is a flowchart illustrating a method 200 of manufacturing a semiconductor device, in accordance with some embodiments of the present disclosure.

The method 200 begins with operation 202 in which a substrate is provided. The substrate may have an array region and an interconnection region. A plurality of isolation layers and first conductive layers may be formed on the substrate. The plurality of isolation layers and the plurality of first conductive layers are stacked alternatively

The method 200 continues with operation 204 in which the plurality of isolation layers and the plurality of first conductive layers are patterned to form a plurality of island structures.

The method 200 continues with operation 206 in which a portion of the isolation layers over the array region are removed to form first openings. Supporting layers may be formed to fill the first openings.

The method 200 continues with operation 208 in which the remaining isolation layers over the array region are removed to expose the first conductive layers.

The method 200 continues with operation 210 in which a capacitor dielectric and a second conductive layer are formed to surround the first conductive layers, thereby defining a plurality of capacitors.

The method 200 continues with operation 212 in which the capacitor dielectric and the second conductive layer over the interconnection region are removed to expose the first conductive layers.

The method 200 is merely an example, and is not intended to limit the present disclosure beyond what is explicitly recited in the claims. Additional operations can be provided before, during, or after each operation of the method 200, and some operations described can be replaced, eliminated, or reordered for additional embodiments of the method. In some embodiments, the method 200 can include further operations not depicted in FIG. 3. In some embodiments, the method 200 can include one or more operations depicted in FIG. 3.

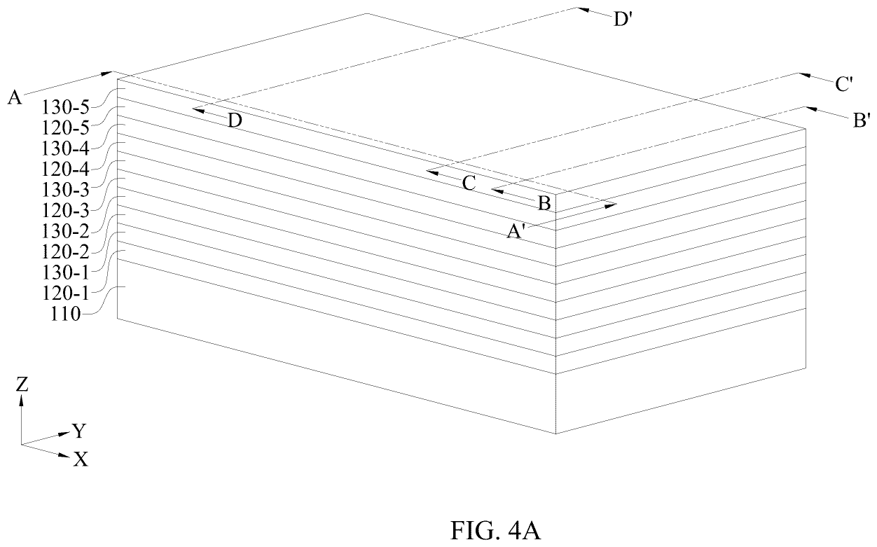

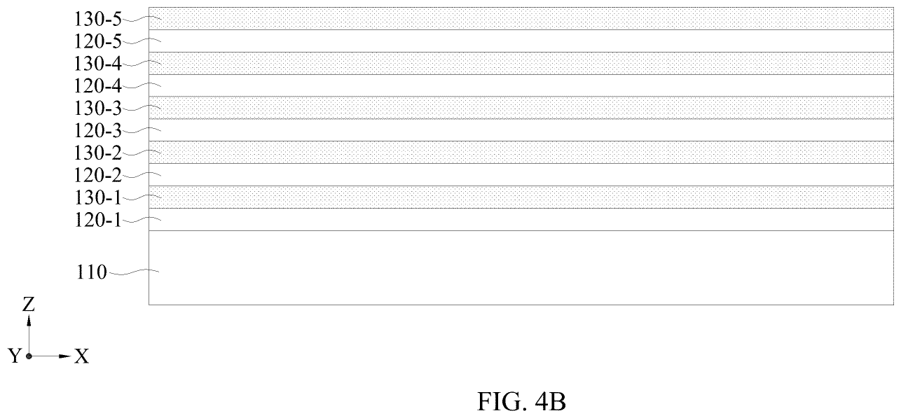

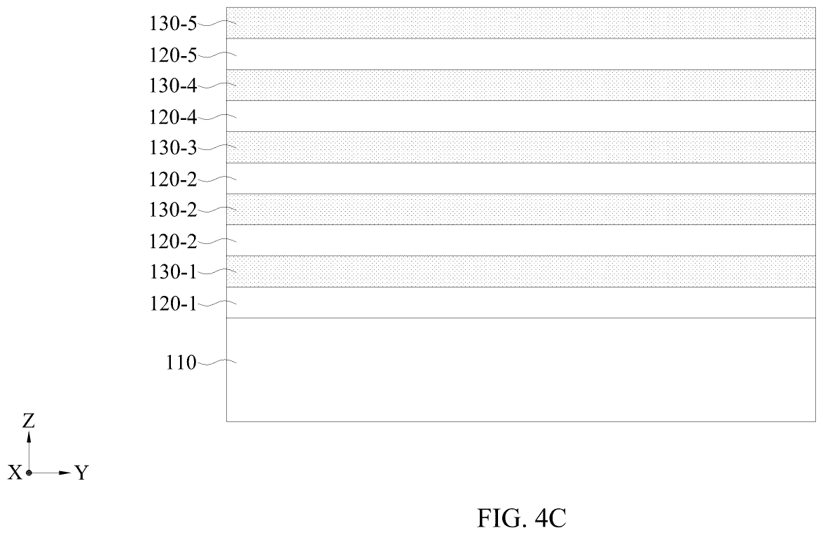

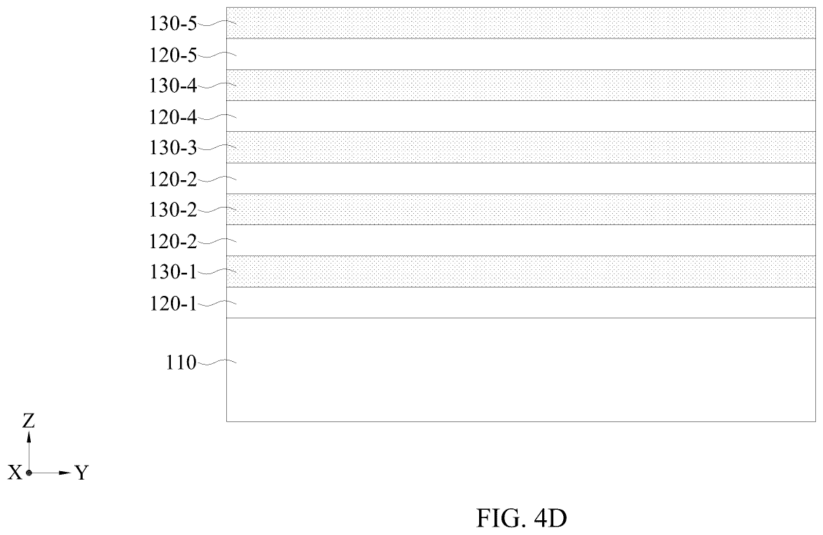

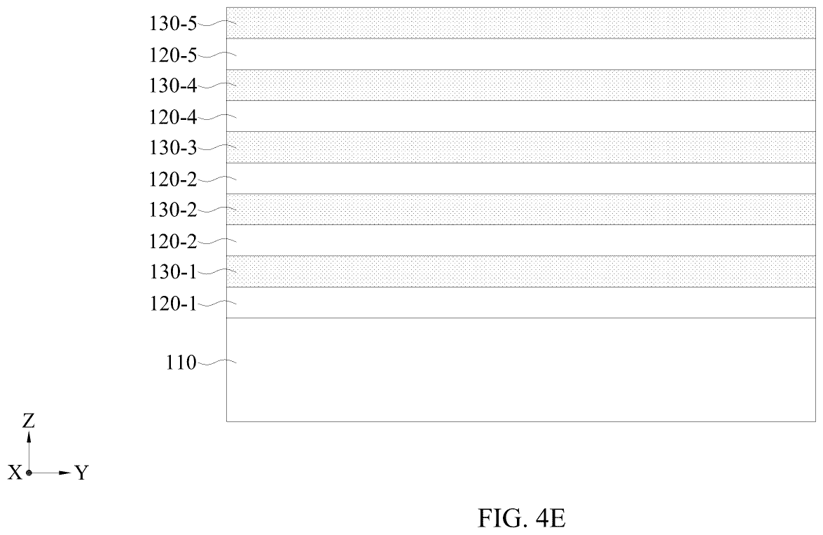

FIG. 4A to FIG. 20A illustrate one or more stages of an exemplary method for manufacturing a semiconductor device 100a according to some embodiments of the present disclosure. FIG. 4B to FIG. 20B are cross-sectional views along line A-A′ of FIG. 4A to FIG. 20A, respectively. FIG. 4C to FIG. 20C are cross-sectional views along line B-B′ of FIG. 4A to FIG. 20A, respectively. FIG. 4D to FIG. 20D are cross-sectional views along line C-C′ of FIG. 4A to FIG. 20A, respectively. FIG. 4E to FIG. 20E are cross-sectional views along line D-D′ of FIG. 4A to FIG. 20A, respectively.

Referring to FIG. 4A, FIG. 4B, FIG. 4C, FIG. 4D, and FIG. 4E, a substrate 110 may be provided. In some embodiments, isolation layers 120-1, 120-2, 120-3, 120-4, and 120-5 as well as conductive layers 130-1, 130-2, 130-3, 130-4, and 130-5 may be alternatively formed over the substrate 110. Each of the isolation layers 120-1, 120-2, 120-3, 120-4, and 120-5 as well as the conductive layers 130-1, 130-2, 130-3, 130-4, and 130-5 may be formed by chemical vapor deposition (CVD), atomic layer deposition (ALD), physical vapor deposition (PVD), low-pressure chemical vapor deposition (LPCVD), plasma-enhanced CVD (PECVD), or other suitable processes. In some embodiments, the isolation layers 120-1, 120-2, 120-3, 120-4, and 120-5 may include a dielectric material, such as silicon oxide. In some embodiments, the conductive layers 130-1, 130-2, 130-3, 130-4, and 130-5 may include a conductive material, such as titanium nitride or other suitable materials.

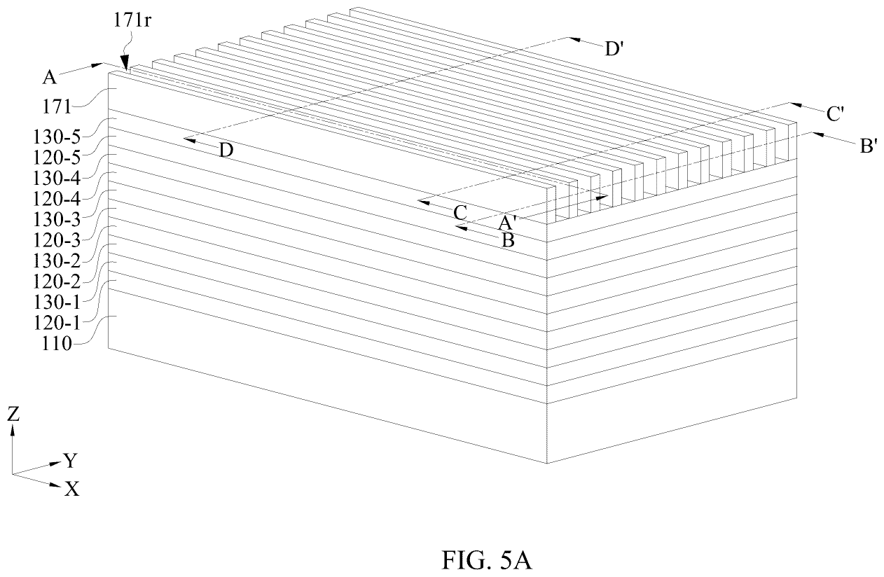

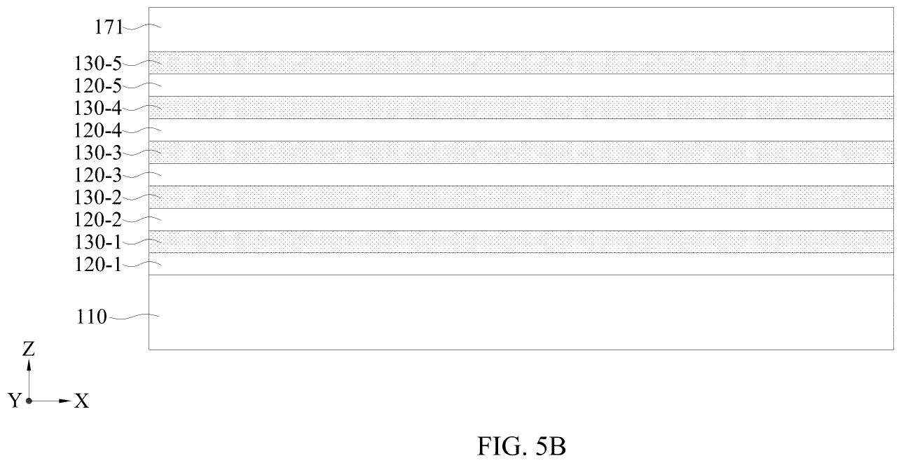

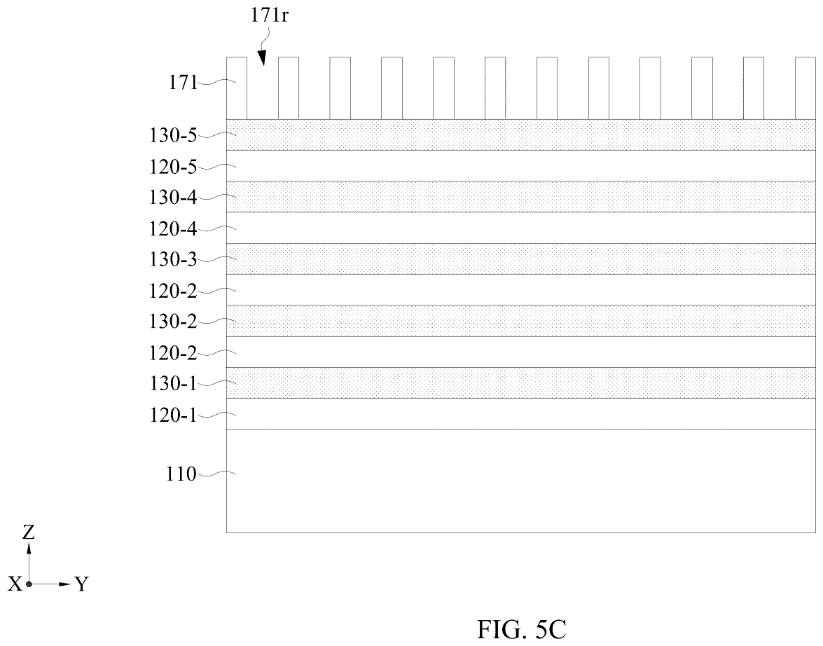

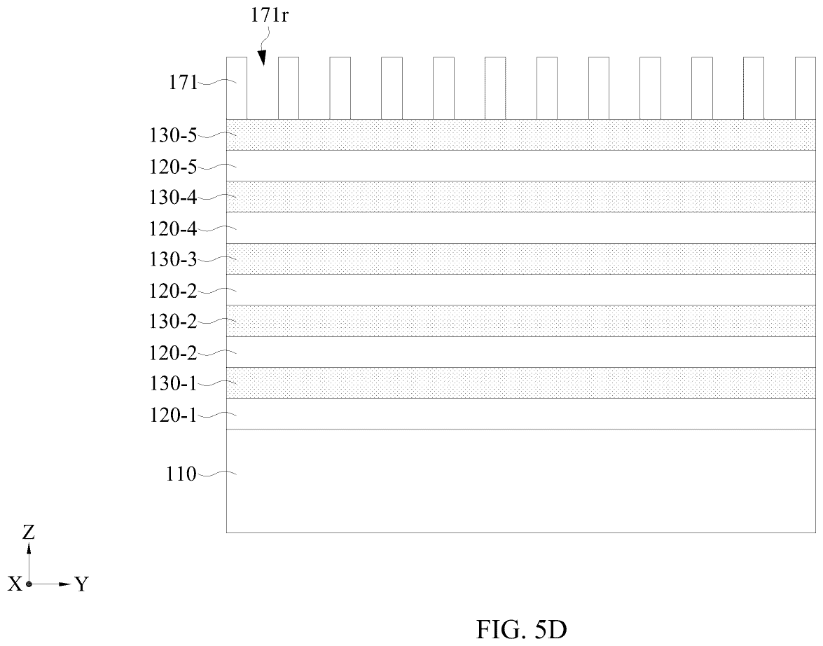

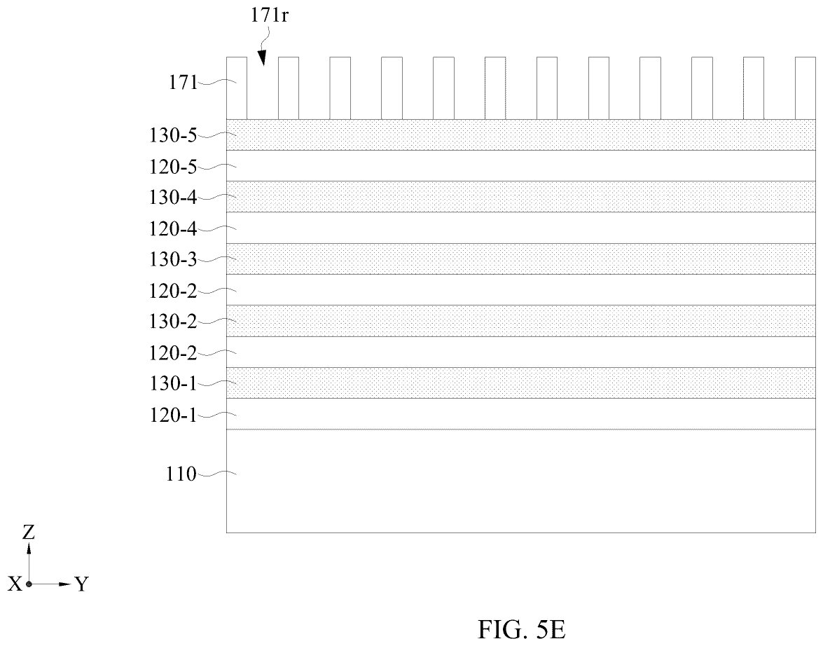

Referring to FIG. 5A, FIG. 5B, FIG. 5C, FIG. 5D, and FIG. 5E, a mask layer 171 may be formed on the conductive layer 130-5. The mask layer 171 may include a negative-tone photoresist (or a negative photoresist) or a positive-tone photoresist (or a positive photoresist). The mask layer 171 may have openings 171r exposing the conductive layer 130-5. In some embodiments, the openings 171r may extend along the X direction.

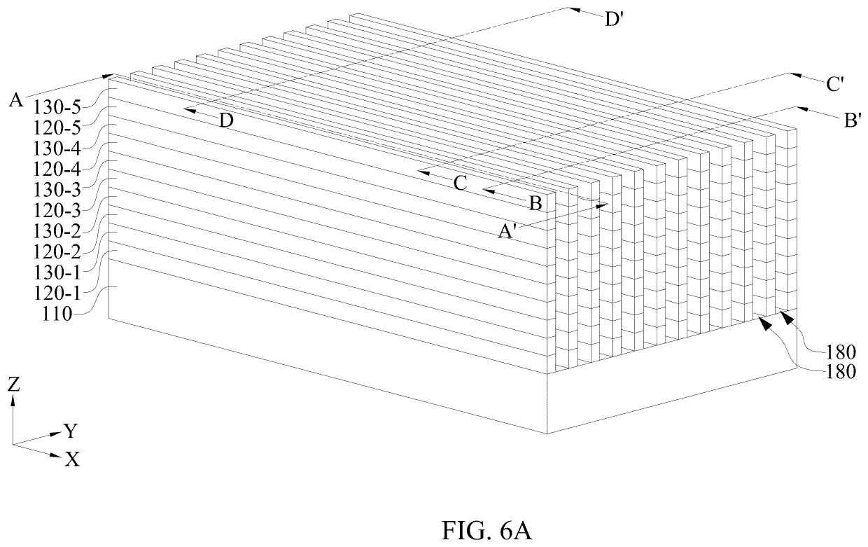

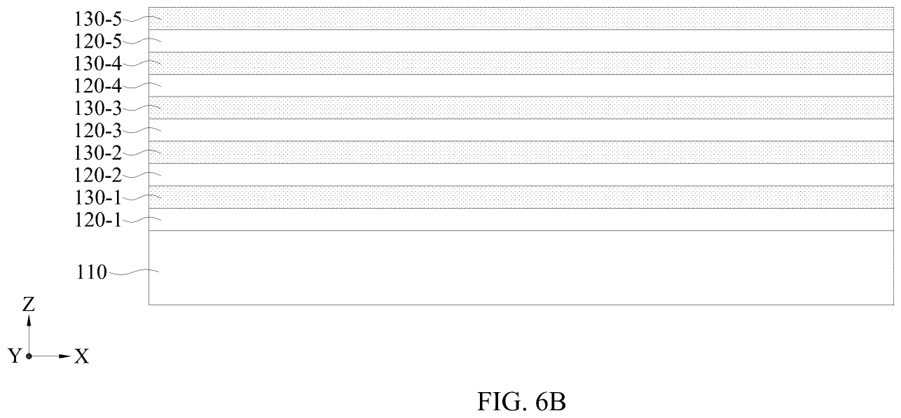

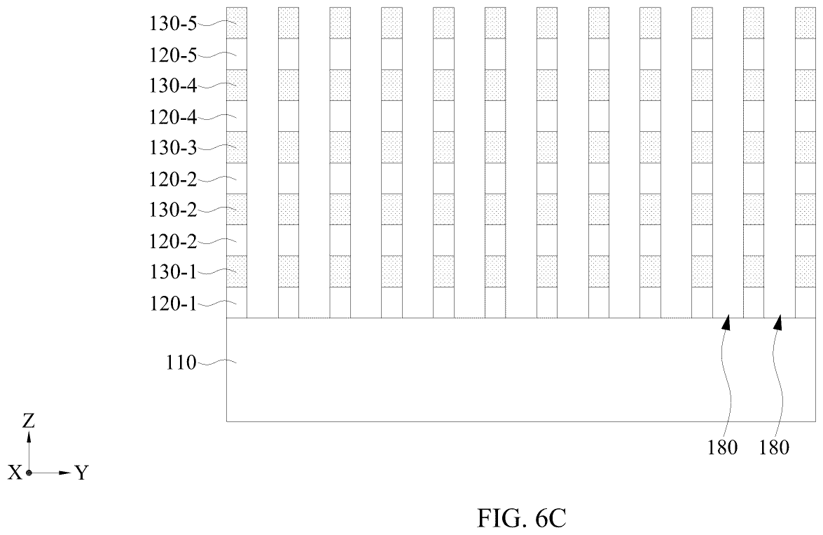

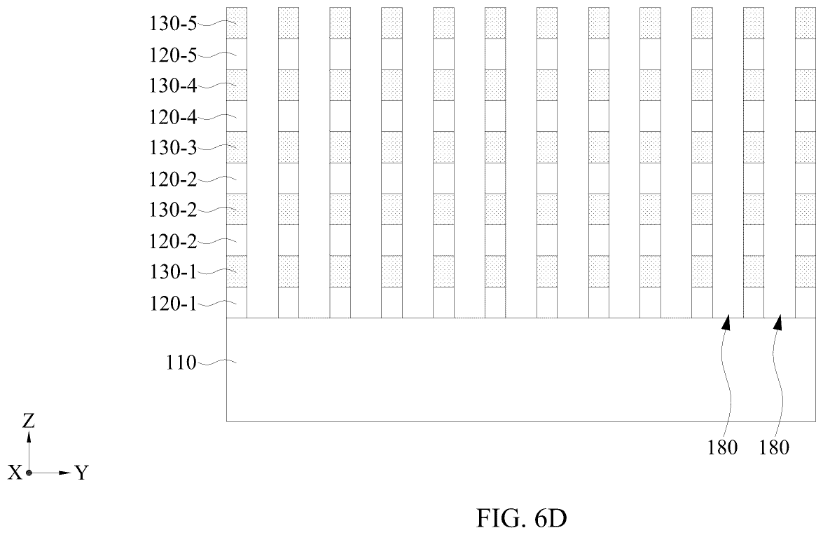

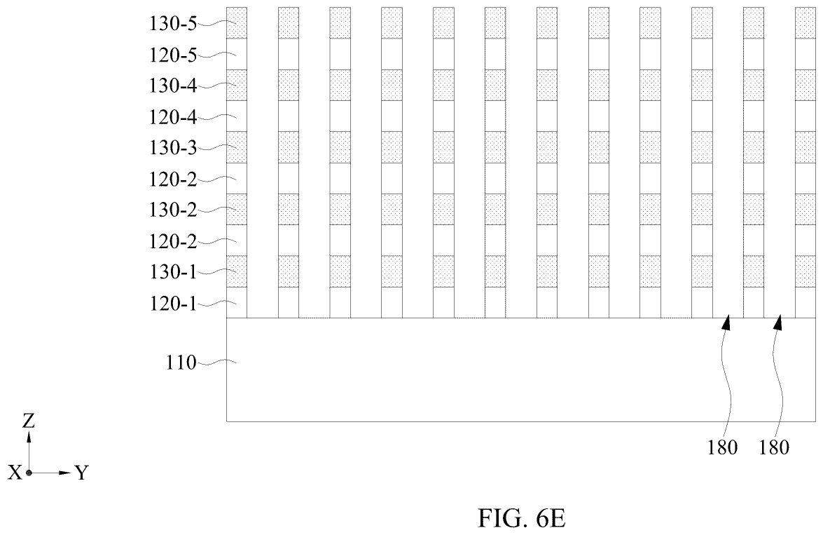

Referring to FIG. 6A, FIG. 6B, FIG. 6C, FIG. 6D, and FIG. 6E, the isolation layers 120-1, 120-2, 120-3, 120-4, and 120-5 and conductive layers 130-1, 130-2, 130-3, 130-4, and 130-5 may be patterned to form island structures 180. A portion of the isolation layers 120-1, 120-2, 120-3, 120-4, and 120-5 may be removed. The mask layer 171 may be removed. A portion of the conductive layers 130-1, 130-2, 130-3, 130-4, and 130-5 may be removed. Each of the island structures 180 may include the isolation layers 120-1, 120-2, 120-3, 120-4, and 120-5 as well as the conductive layers 130-1, 130-2, 130-3, 130-4, and 130-5. Each of the island structures 180 may extend along the X direction. The first capacitor electrode of a capacitor may be defined in this stage.

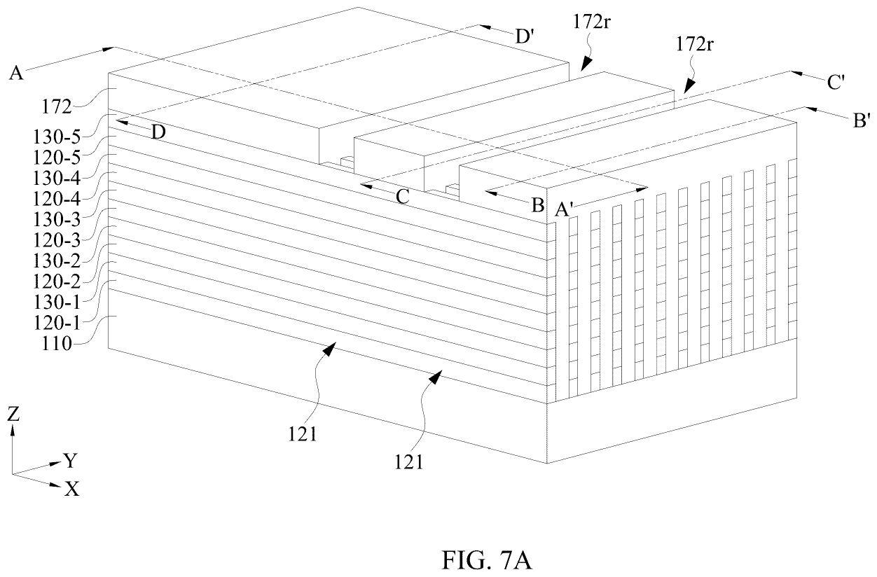

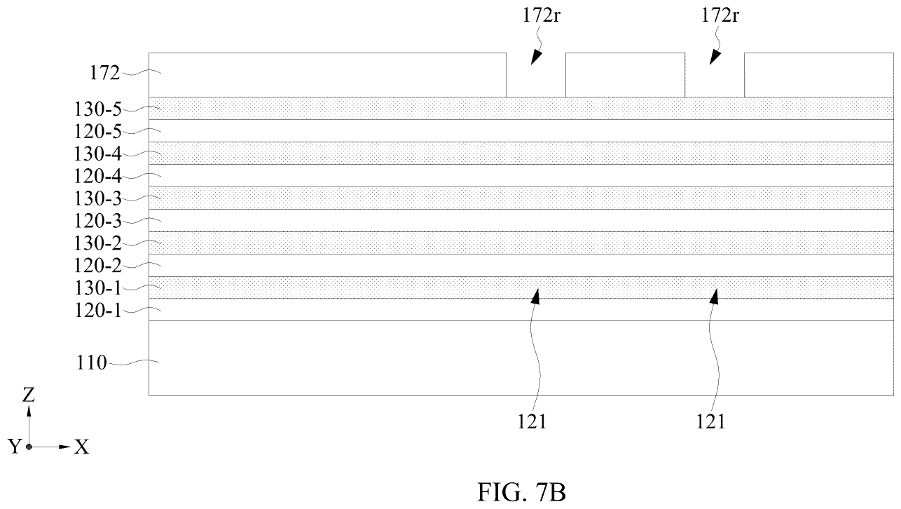

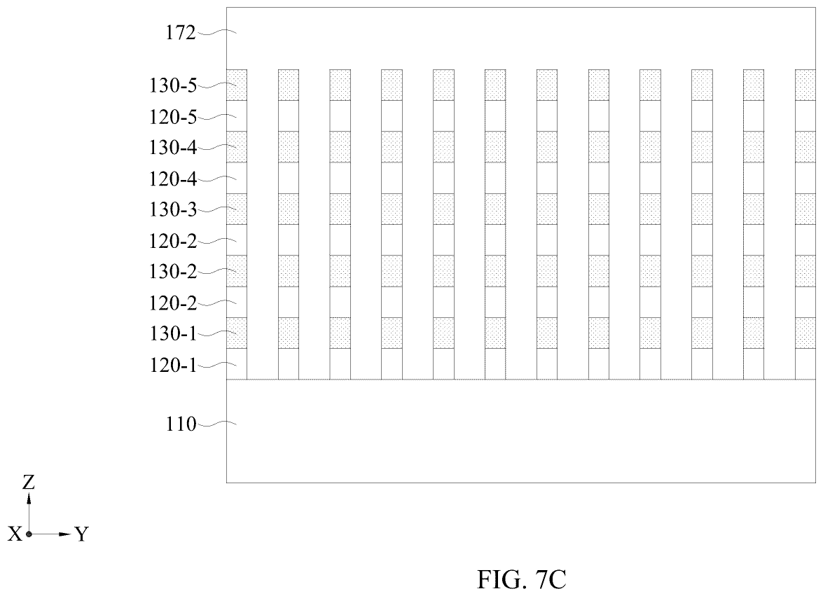

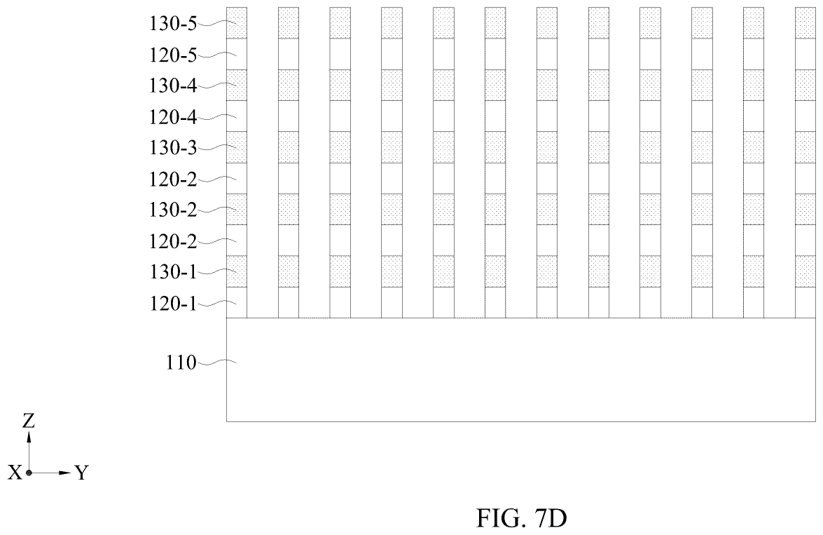

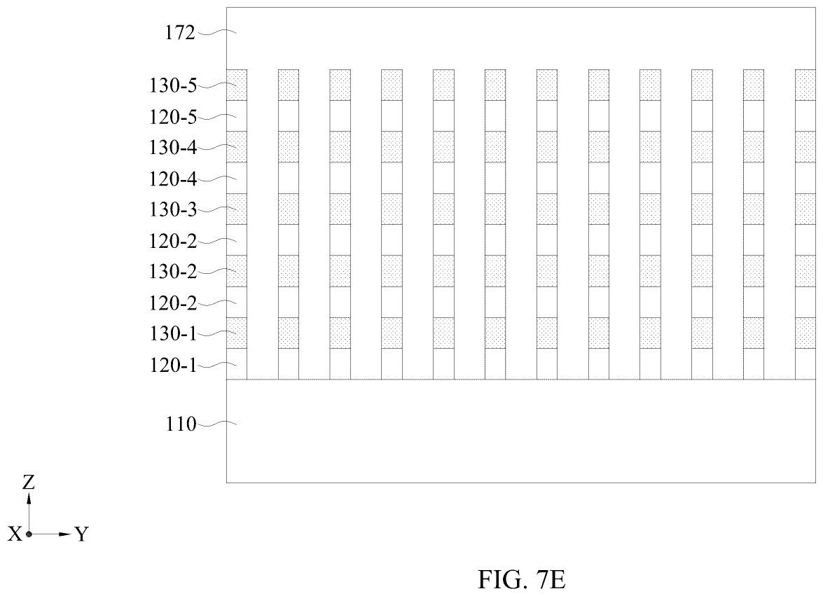

Referring to FIG. 7A, FIG. 7B, FIG. 7C, FIG. 7D, and FIG. 7E, a mask layer 172 may be formed to cover the island structures 180. The mask layer 172 may include a negative-tone photoresist or a positive-tone photoresist. The mask layer 172 may include openings 172r exposing the island structures 180. The opening 172r may extend along the Y direction. In some embodiments, portions 121 of the isolation layers 120-1, 120-2, 120-3, 120-4, and 120-5 may be exposed by the openings 172r.

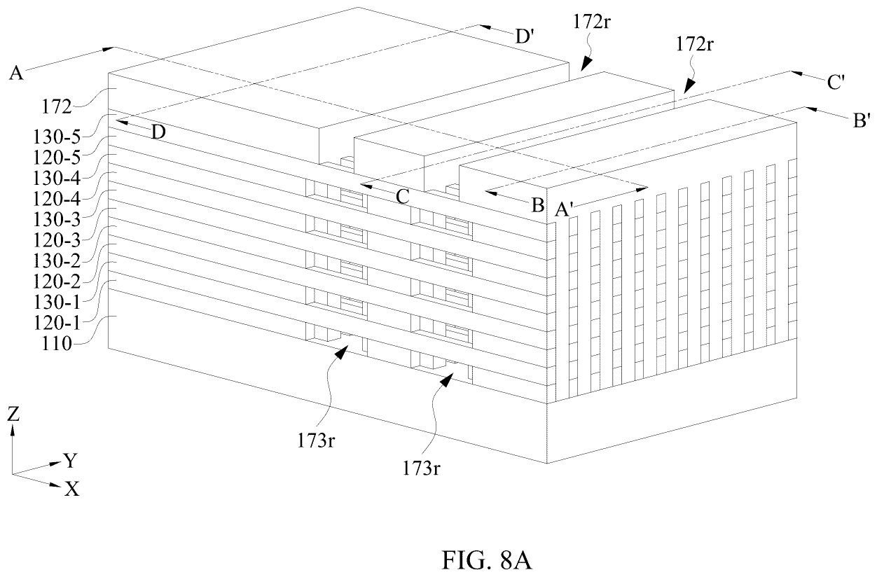

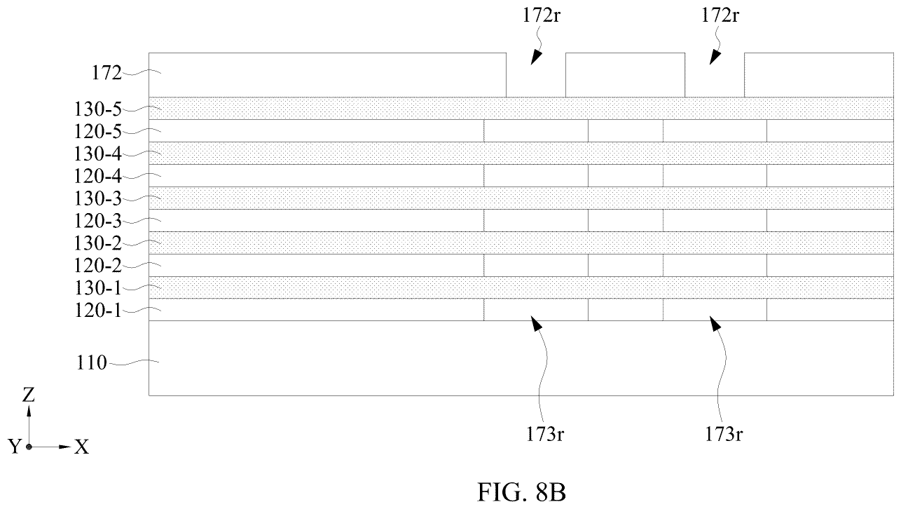

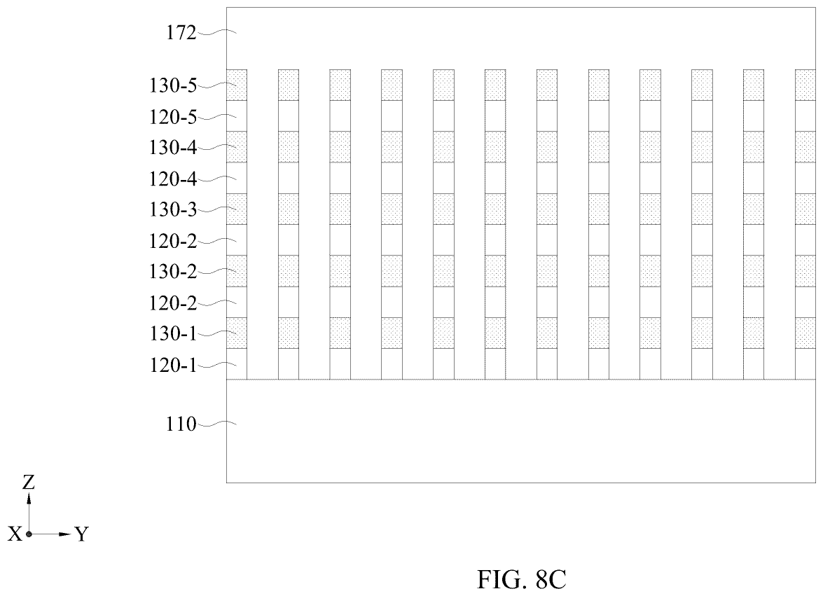

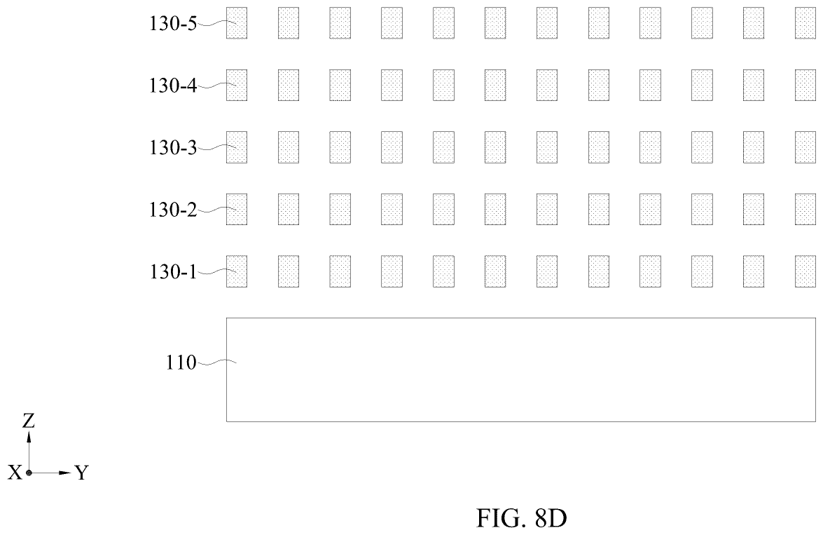

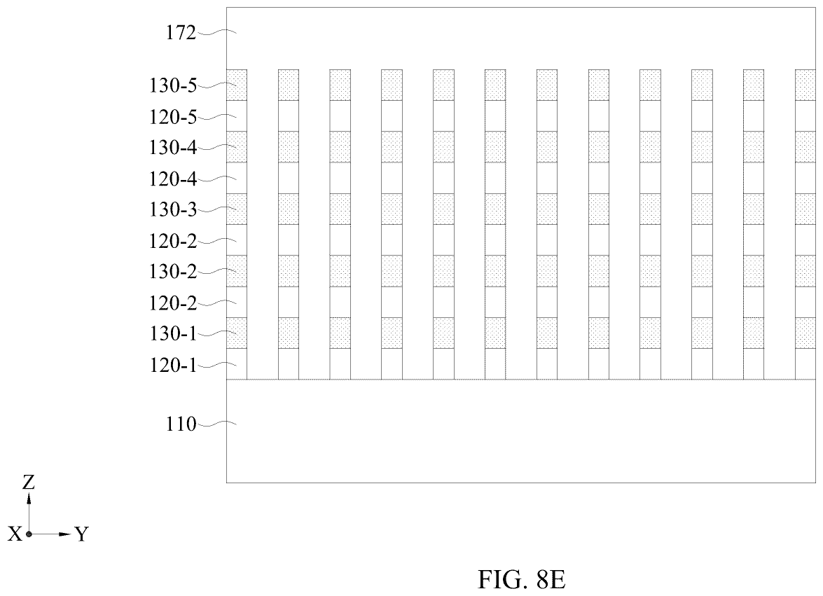

Referring to FIG. 8A, FIG. 8B, FIG. 8C, FIG. 8D, and FIG. 8E, the isolation layers 120-1, 120-2, 120-3, 120-4, and 120-5, exposed by the openings 172r, may be removed. The portions 121 of the isolation layers 120-1, 120-2, 120-3, 120-4, and 120-5 may be removed. A plurality of openings 173r may be formed.

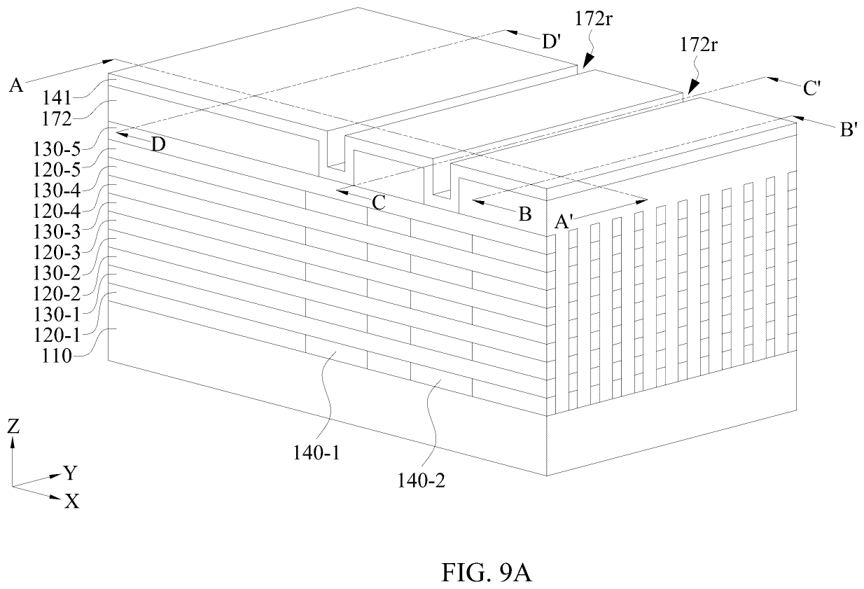

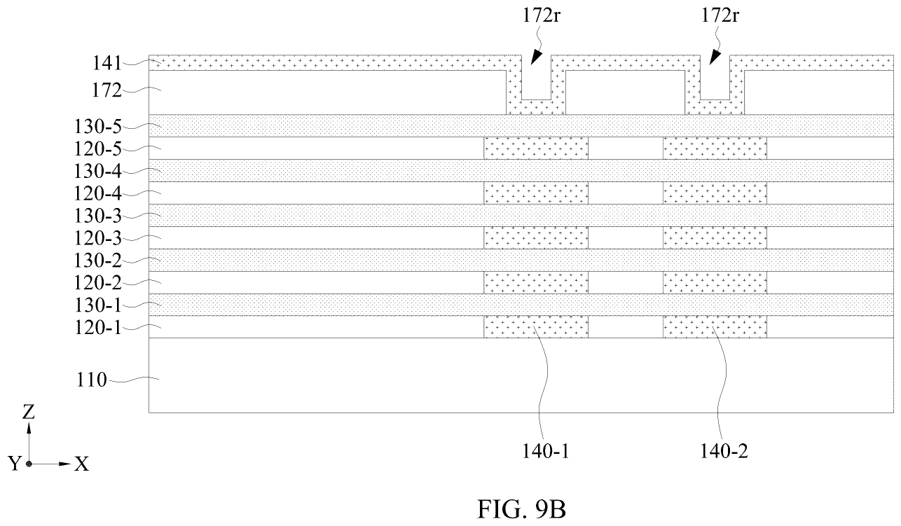

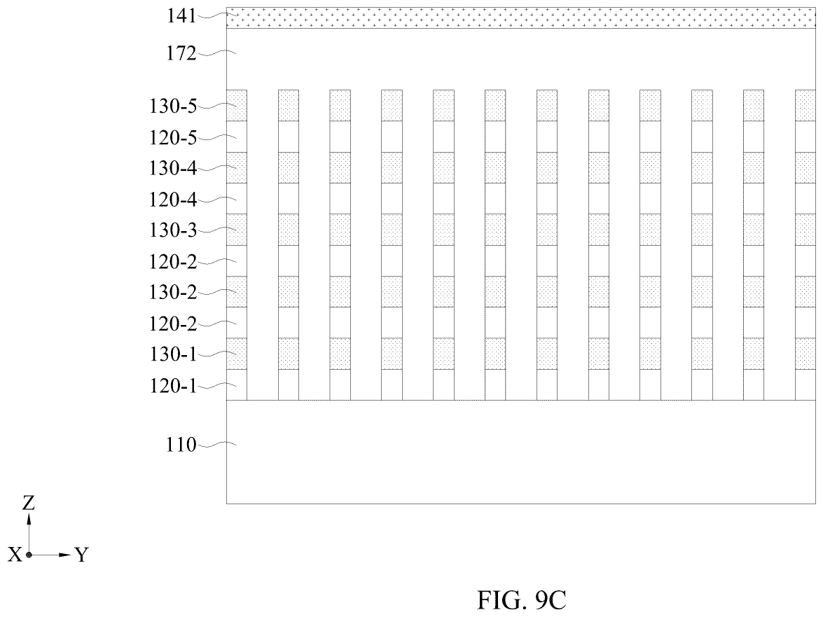

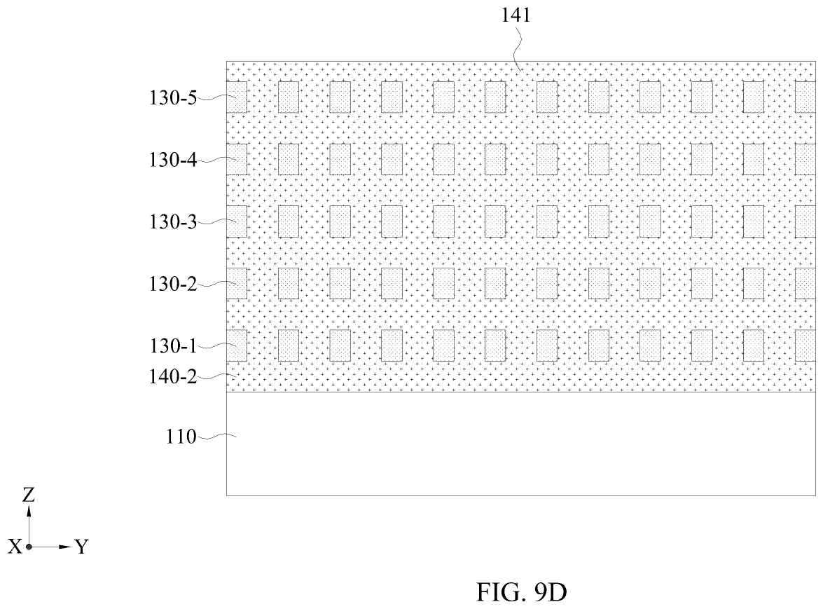

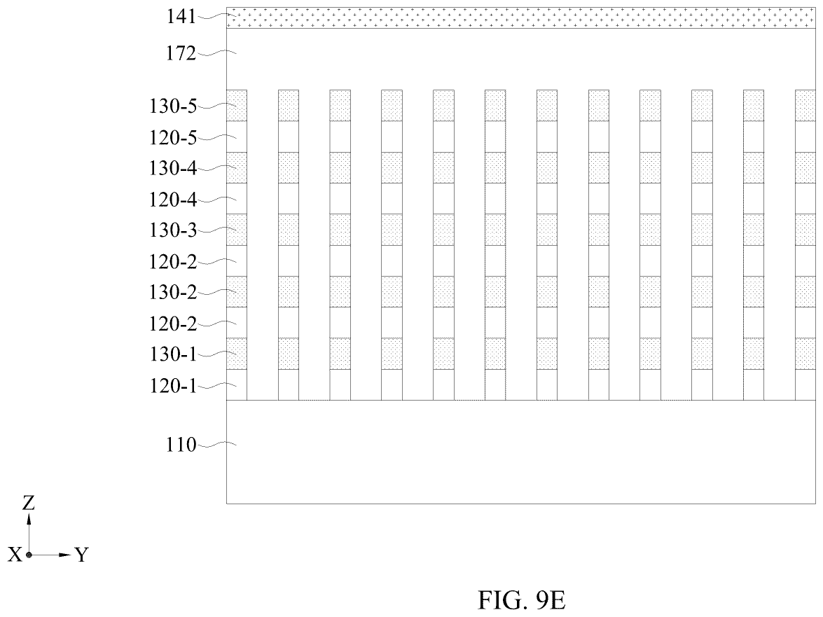

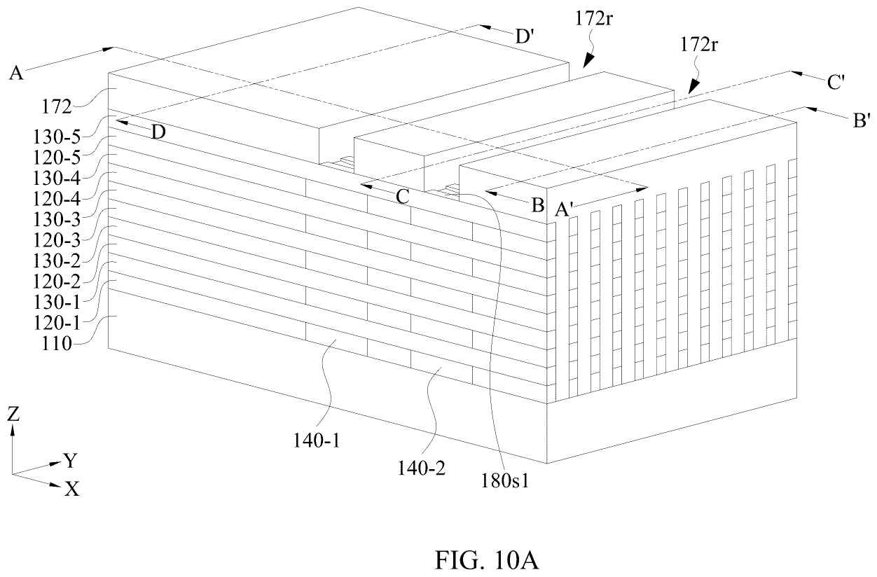

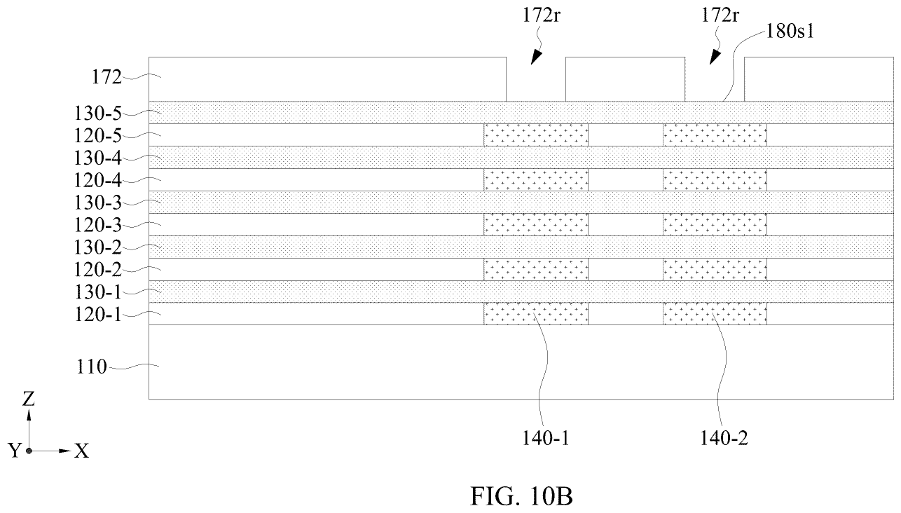

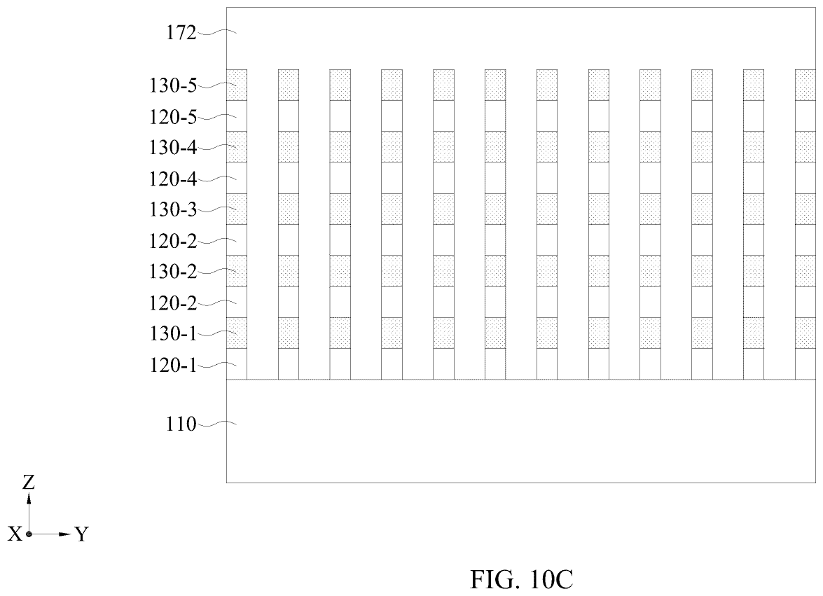

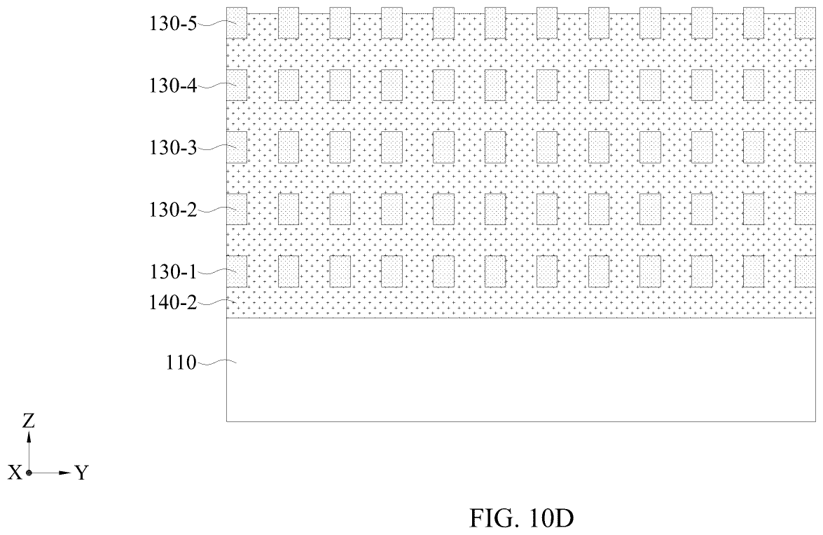

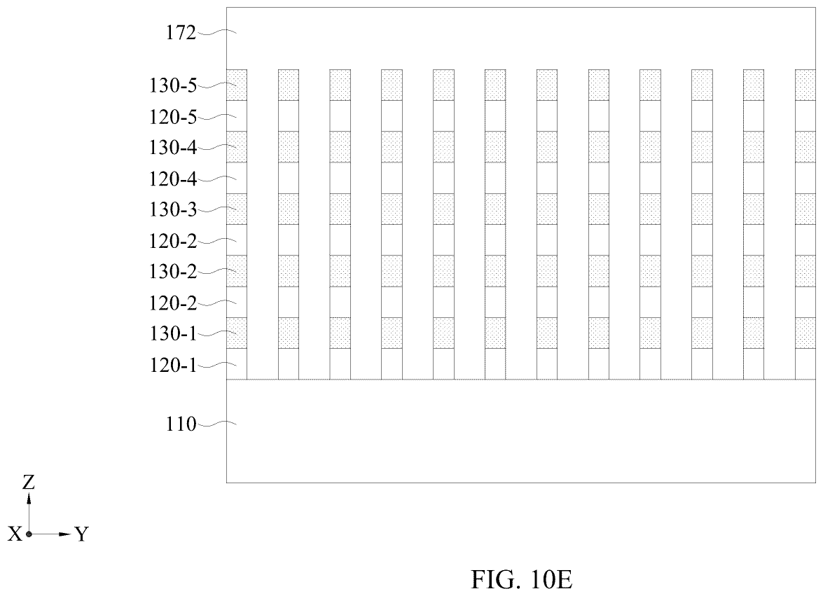

Referring to FIG. 9A, FIG. 9B, FIG. 9C, FIG. 9D, and FIG. 9E, a dielectric layer 141 may be formed to fill the openings 173r. Supporting layers 140-1 and 140-2 may be formed. The supporting layer 140-1 may extend along the Y direction. In some embodiments, the supporting layer 140-1 may surround or enclose the conductive layers 130-1, 130-2, 130-3, 130-4, and 130-5. In some embodiments, the supporting layers 140-1 and 140-2 may be inserted between, for example, two opposite lateral surfaces (not annotated in the figures) of the isolation layers 120-1, 120-2, 120-3, 120-4, and 120-5. In some embodiments, the supporting layers 140-1 and 140-2 may be inserted between, for example, two opposite lateral surfaces (not annotated in the figures) of the conductive layers 130-1, 130-2, 130-3, 130-4, or 130-5. In some embodiments, the supporting layers 140-1 and 140-2 may enforce the framework of the intermediate structure shown in FIG. 10A to FIG. 20A. In some embodiments, the dielectric layer 141 may include a dielectric material, such as silicon nitride. The material of the dielectric layer 141 may be different from that of the isolation layers 120-1, 120-2, 120-3, 120-4, and 120-5. The dielectric layer 141 may be formed by, CVD, PVD, ALD, LPCVD, PECVD, or other suitable processes.

Referring to FIG. 10A, FIG. 10B, FIG. 10C, FIG. 10D, and FIG. 10E, a portion of the dielectric layer 141 may be removed to expose the dielectric layer 182. The dielectric layer 141 over an upper surface 180s1 (or an upper surface) of the isolation structures 180 may be removed. The dielectric layer 141 over the conductive layer 135 may be removed. The dielectric layer 141 over the mask layer 172 may be removed. The dielectric layer 141 may be removed by, for example, a wet etching technique.

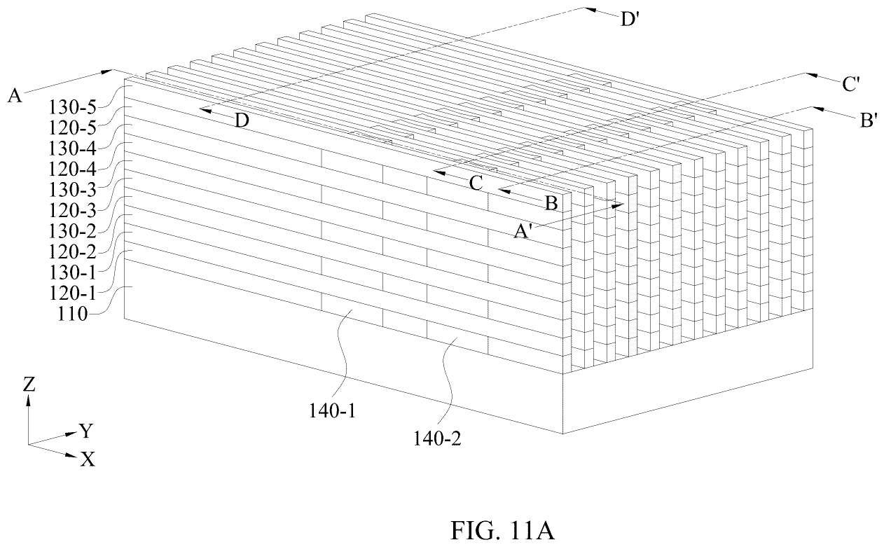

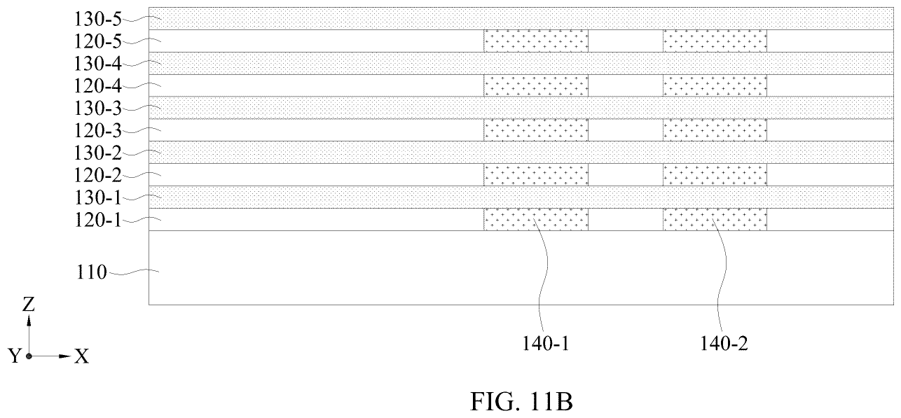

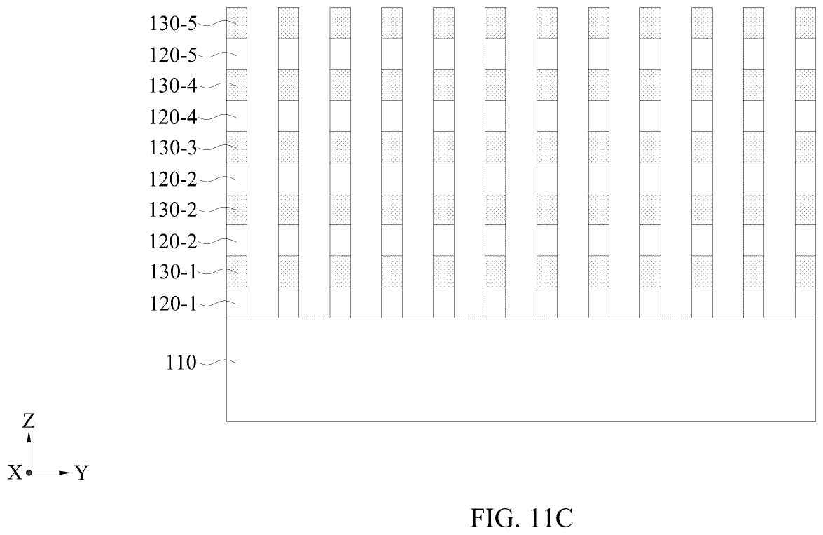

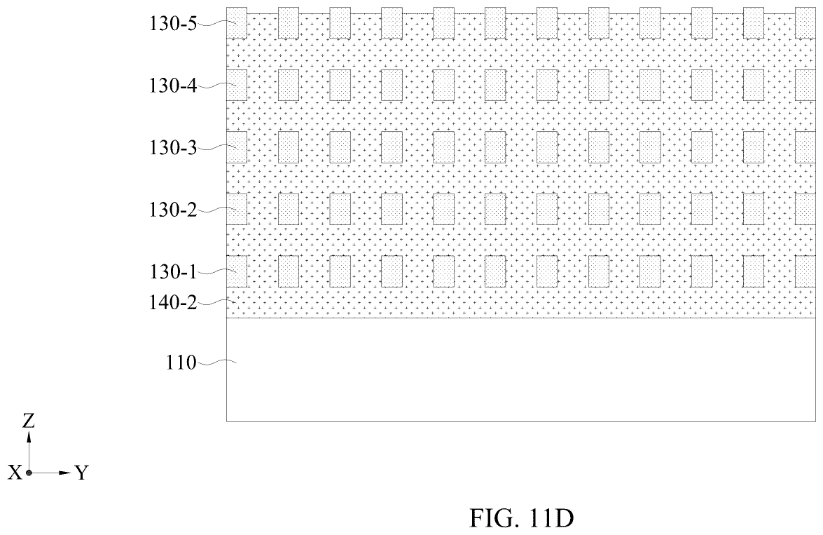

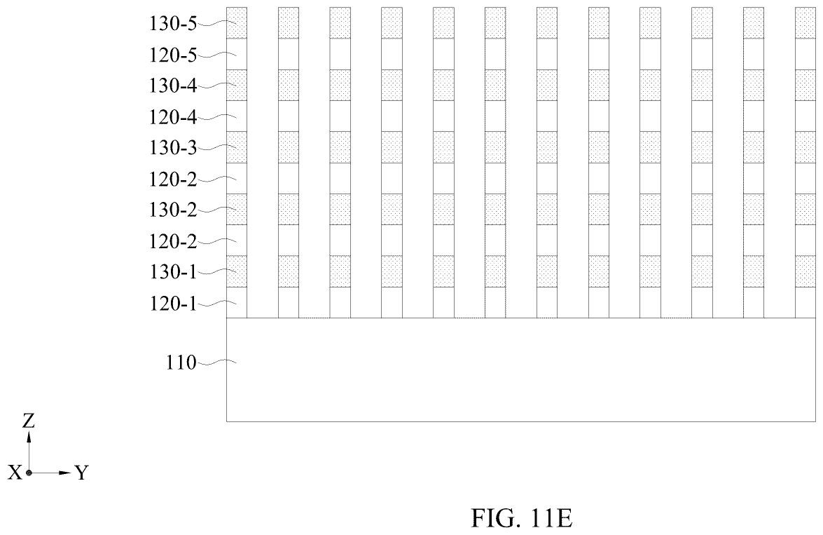

Referring to FIG. 11A, FIG. 11B, FIG. 11C, FIG. 11D, and FIG. 11E, the mask layer 172 may be removed. The conductive layer 130-5 may be exposed.

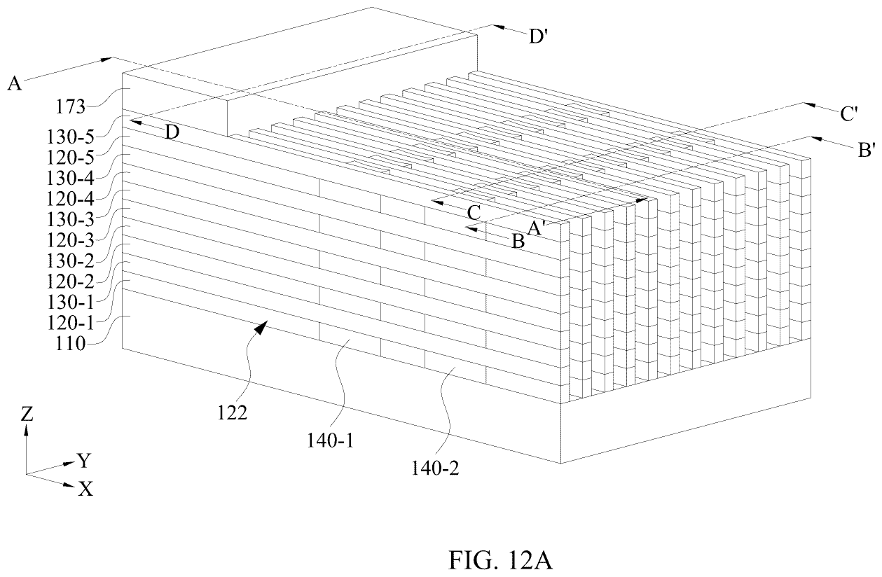

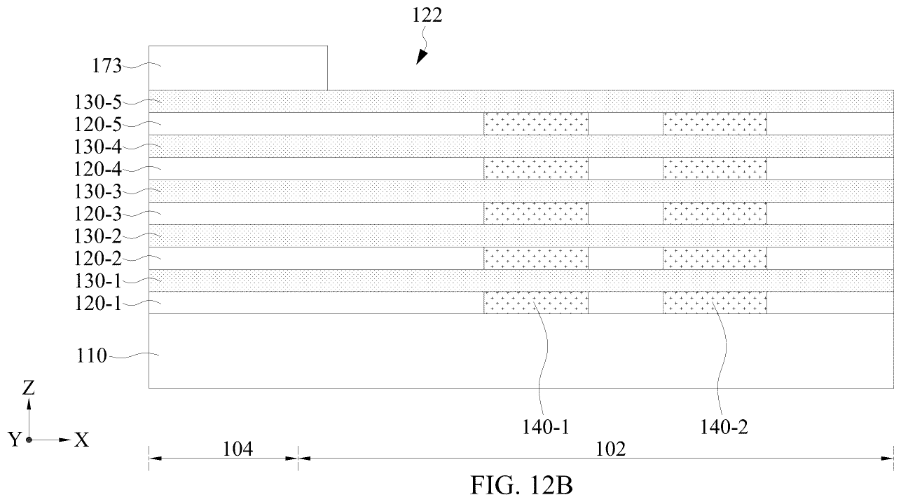

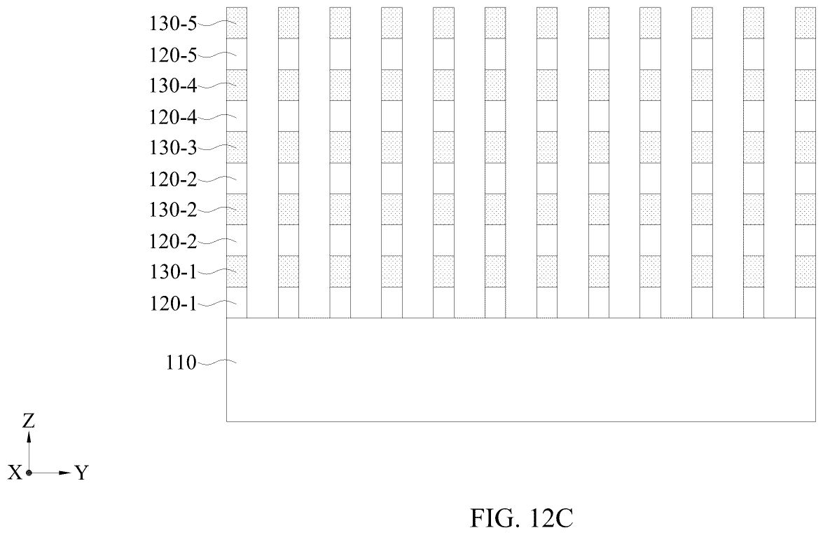

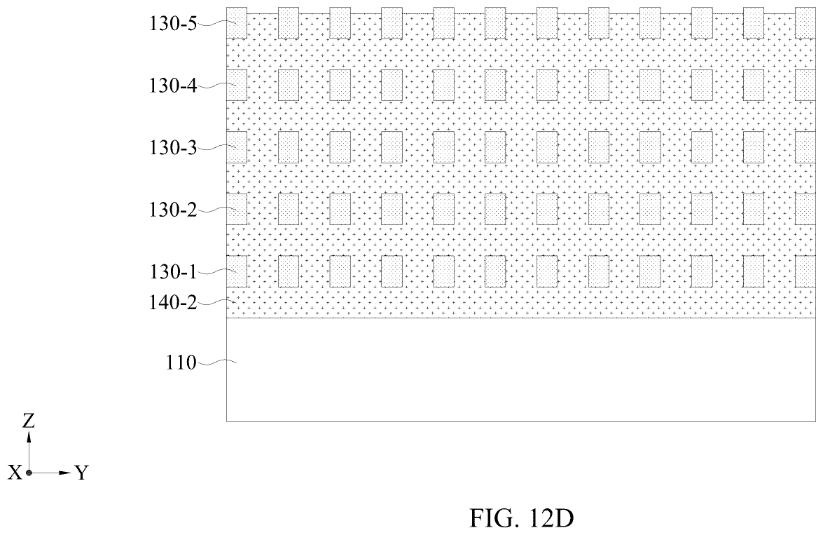

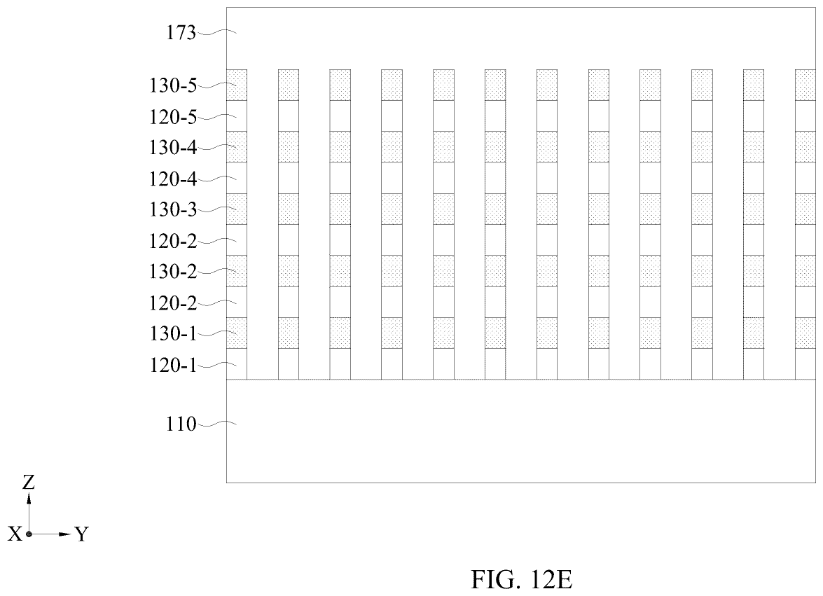

Referring to FIG. 12A, FIG. 12B, FIG. 12C, FIG. 12D, and FIG. 12E, a mask layer 173 may be formed to cover a portion 122 of the isolation layers 120-1, 120-2, 120-3, 120-4, and 120-5 as well as the conductive layers 130-1, 130-2, 130-3, 130-4, and 130-5. The mask layer 173 may include a negative-tone photoresist or a positive-tone photoresist. In some embodiments, the mask layer 173 may be configured to define an array region 102 and an interconnection region 104 of the semiconductor device. The array region 102 may be a region on which capacitors are formed. The interconnection region 104 may be a region on which interconnection traces are formed. In some embodiments, the isolation layers 120-1, 120-2, 120-3, 120-4, and 120-5 as well as the conductive layers 130-1, 130-2, 130-3, 130-4, and 130-5 of the array region 102 may be exposed from the mask layer 173. In some embodiments, the isolation layers 120-1, 120-2, 120-3, 120-4, and 120-5 as well as the conductive layers 130-1, 130-2, 130-3, 130-4, and 130-5 of the interconnection region 104 may be covered from the mask layer 173.

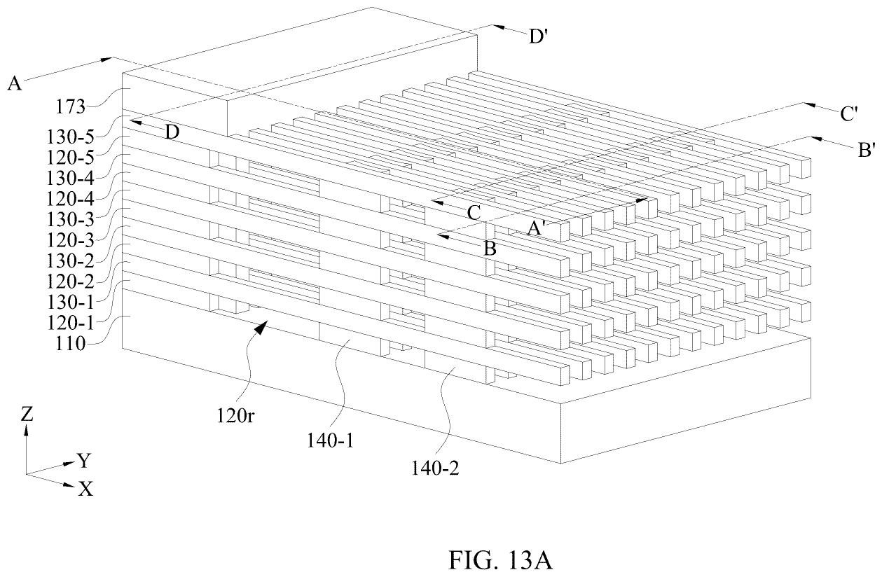

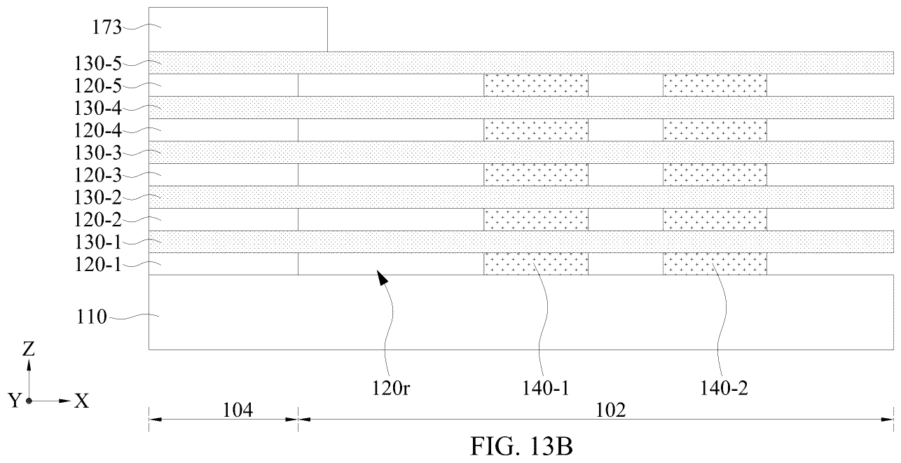

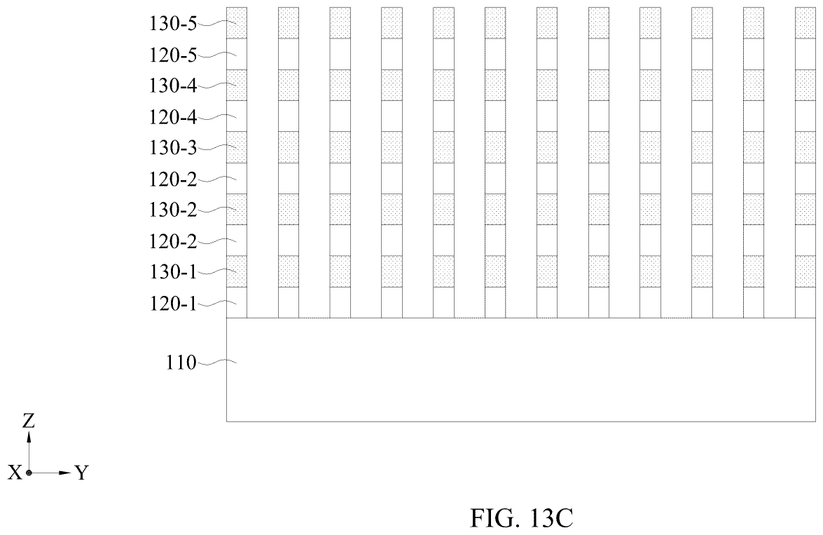

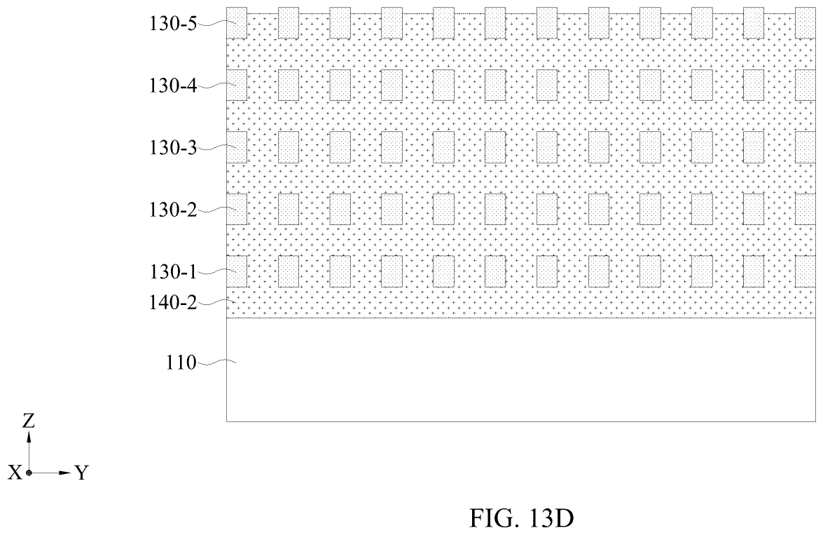

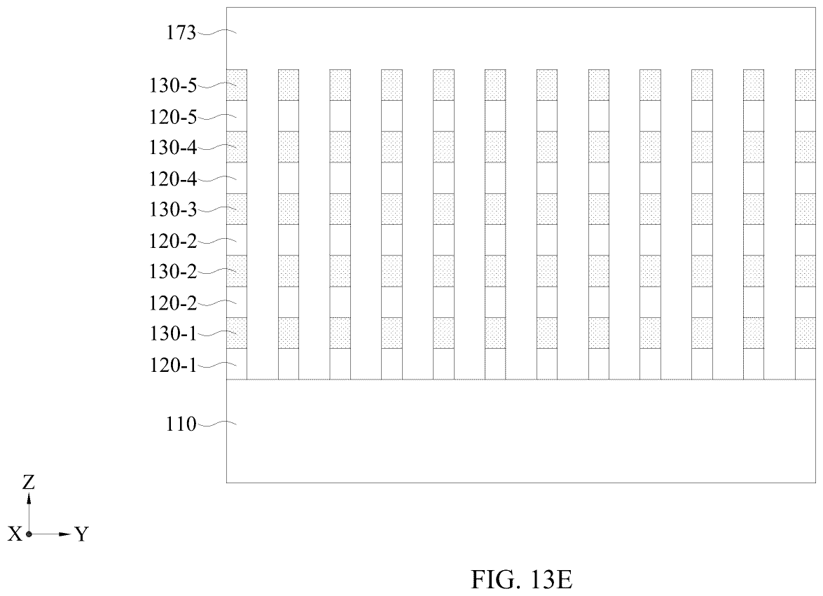

Referring to FIG. 13A, FIG. 13B, FIG. 13C, FIG. 13D, and FIG. 13E, an etching technique may be performed. The isolation layers 120-1, 120-2, 120-3, 120-4, and 120-5 exposed from the mask layer 173 may be removed. The portions 122 of the isolation layers 120-1, 120-2, 120-3, 120-4, and 120-5 may be removed. The conductive layers 130-1, 130-2, 130-3, 130-4, and 130-5 may be exposed. The isolation layers 120-1, 120-2, 120-3, 120-4, and 120-5 may be removed by, for example, a wet etching technique. An opening 120r may be defined. The supporting layers 140-1 and 140-2 may be configured to support the conductive layers 130-1, 130-2, 130-3, 130-4, and 130-5, which prevents the conductive layers 130-1, 130-2, 130-3, 130-4, and 130-5 from collapsing.

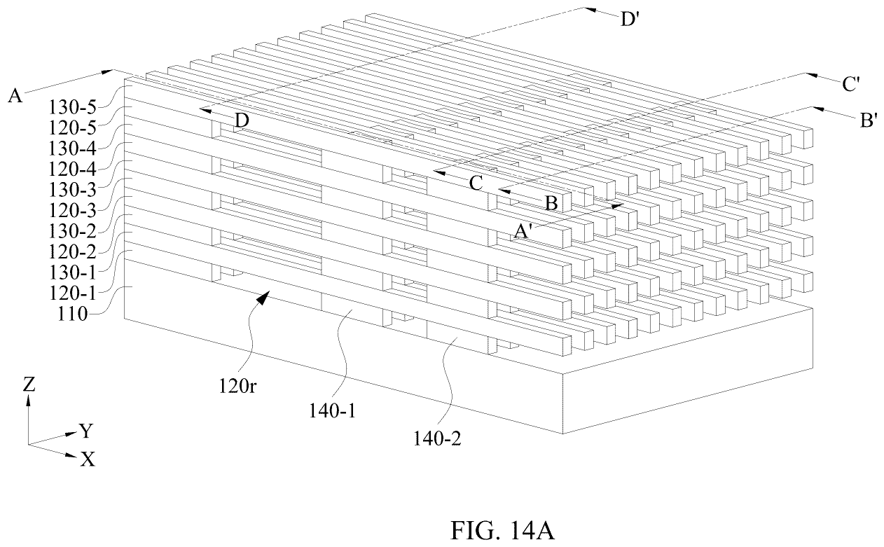

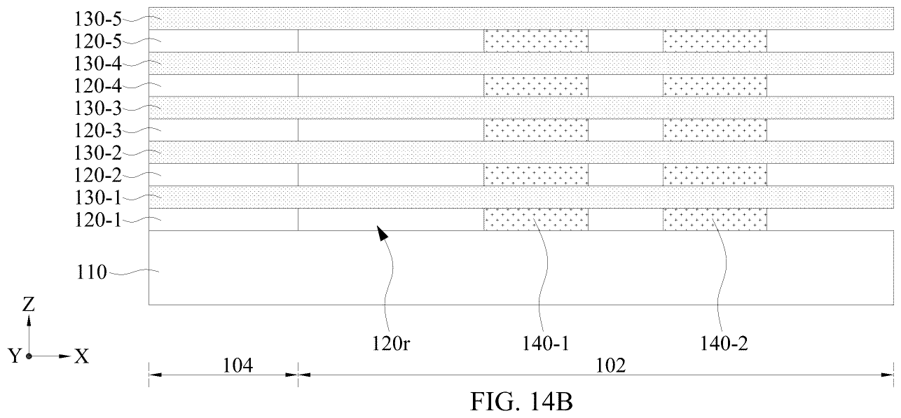

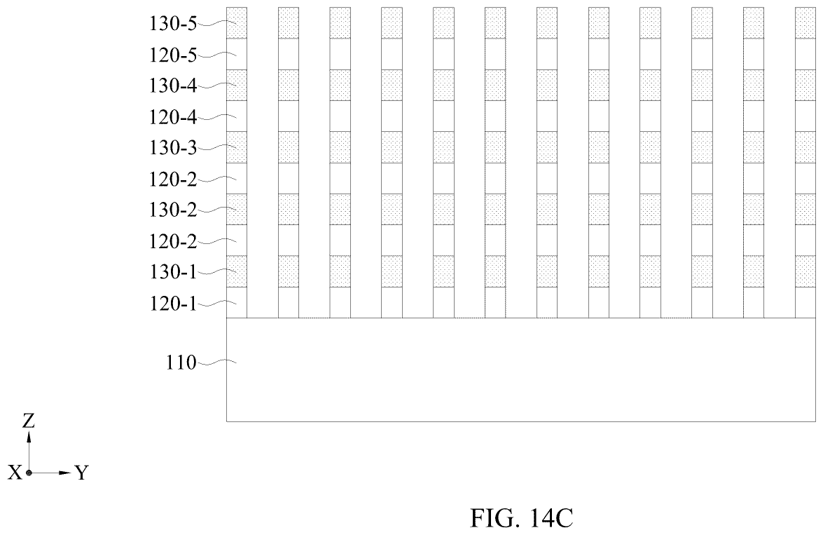

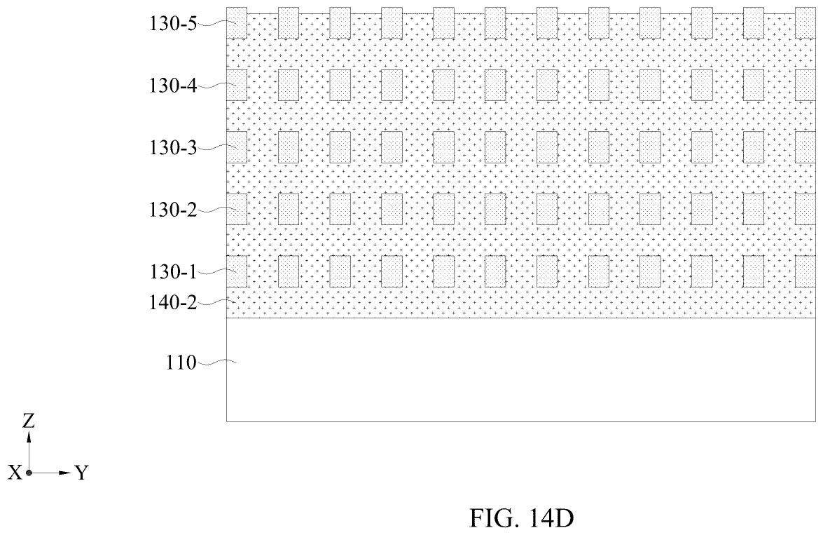

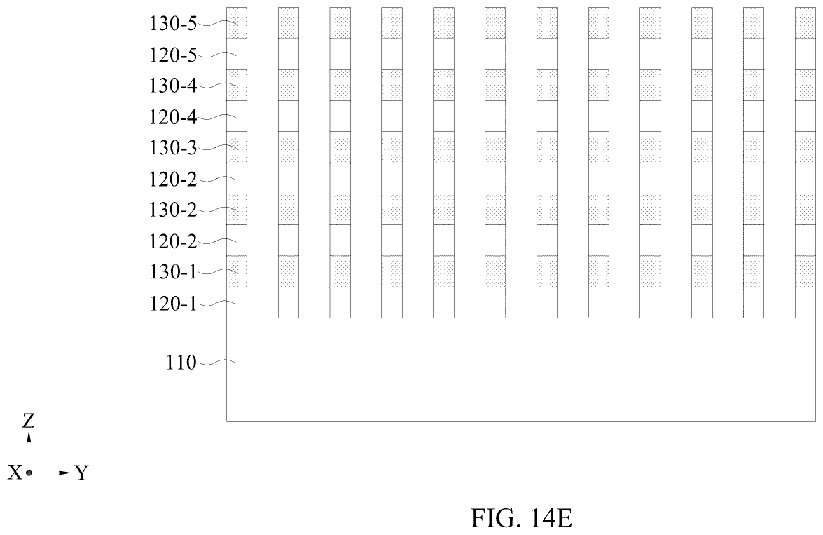

Referring to FIG. 14A, FIG. 14B, FIG. 14C, FIG. 14D, and FIG. 14E, the mask layer 173 may be removed.

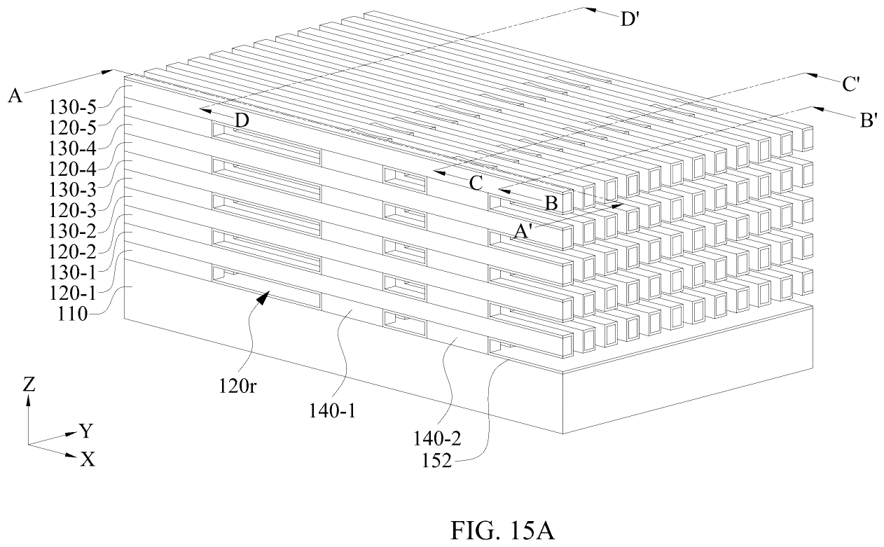

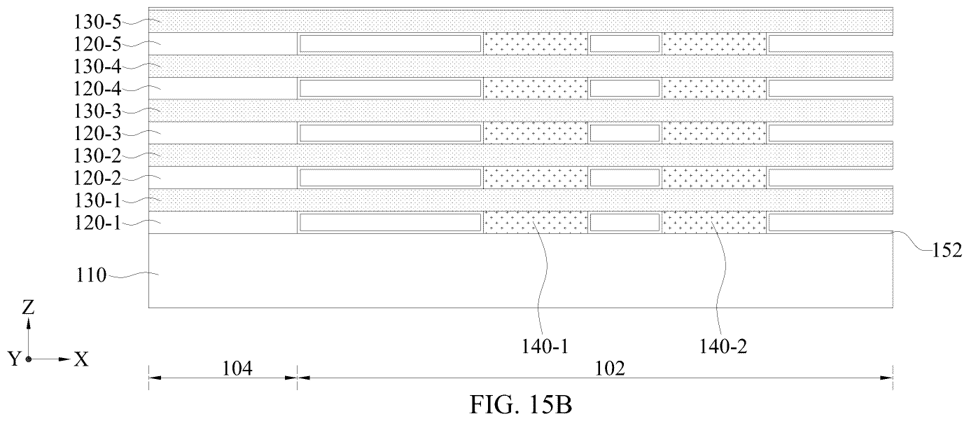

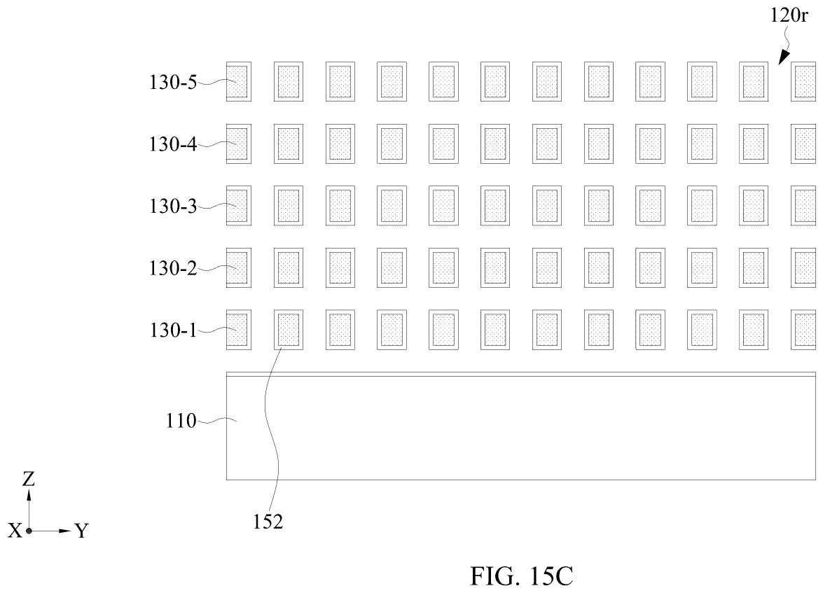

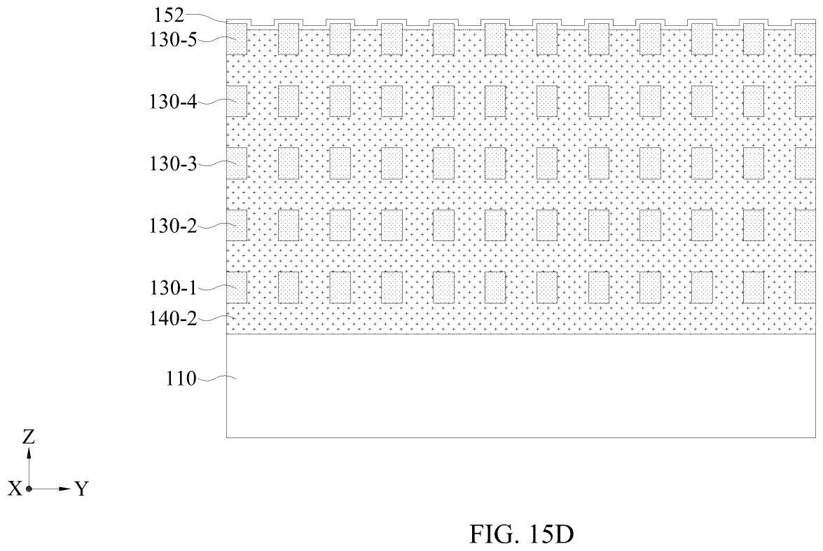

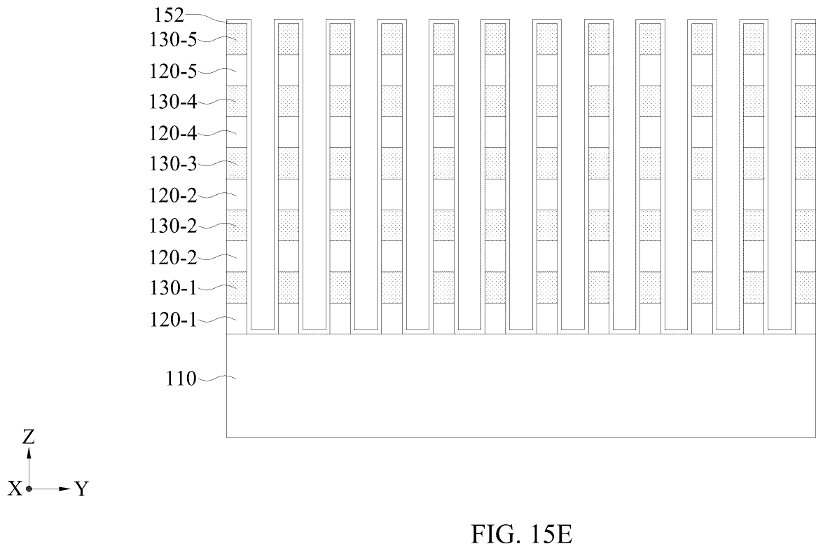

Referring to FIG. 15A, FIG. 15B, FIG. 15C, FIG. 15D, and FIG. 15E, a capacitor dielectric 152 may be formed within the opening 120r. In some embodiments, the capacitor dielectric 152 may be conformally formed on the conductive layers 130-1, 130-2, 130-3, 130-4, and 130-5. In some embodiments, the capacitor dielectric 152 may be formed on the array region 102. In some embodiments, the capacitor dielectric 152 may be formed on the interconnection region 104. The capacitor dielectric 152 may be formed by, for example, ALD, CVD, PVD, LPCVD, PECVD, or other suitable processes. In some embodiments, the capacitor dielectric 152 may include a high-k material.

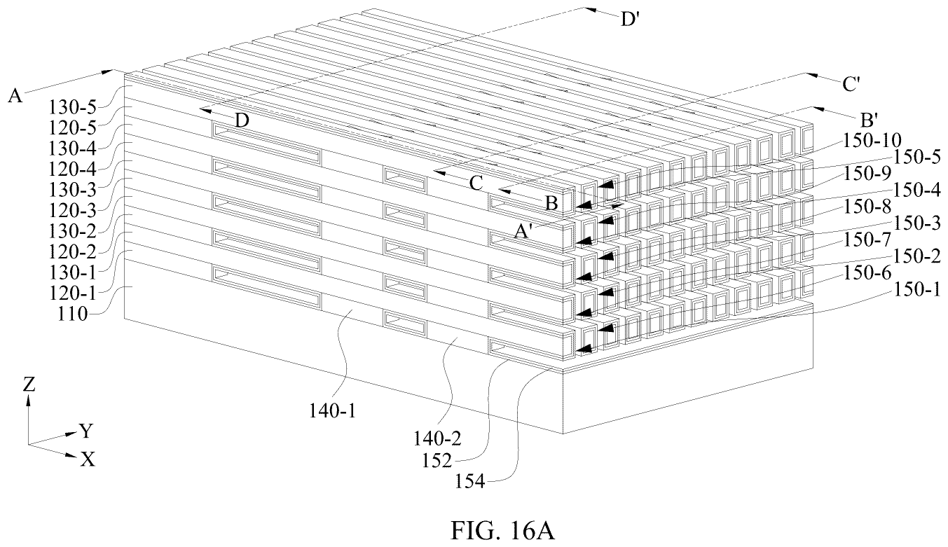

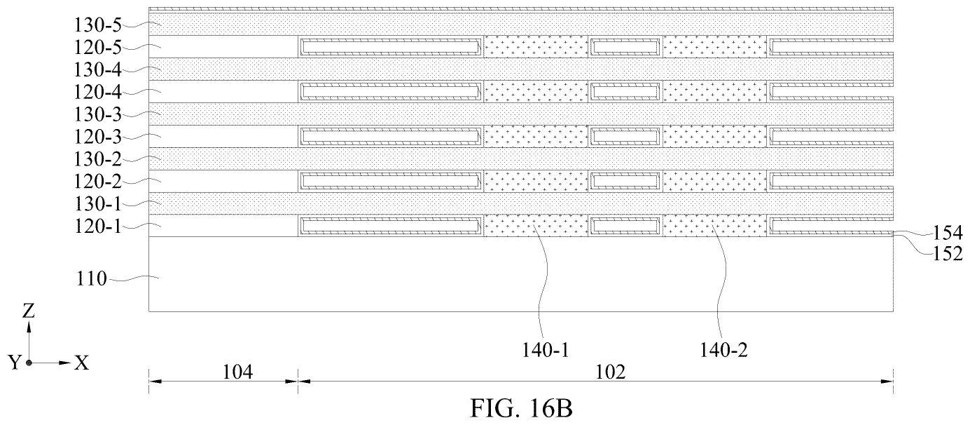

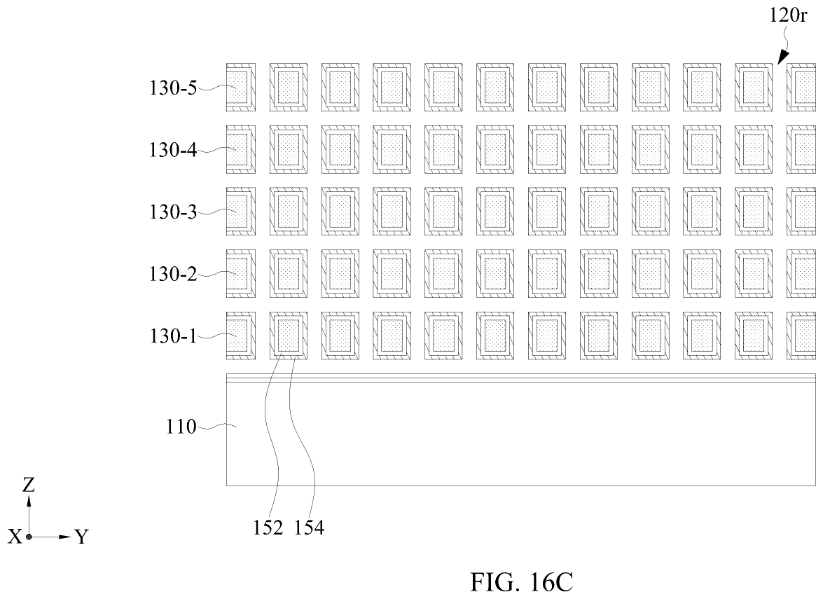

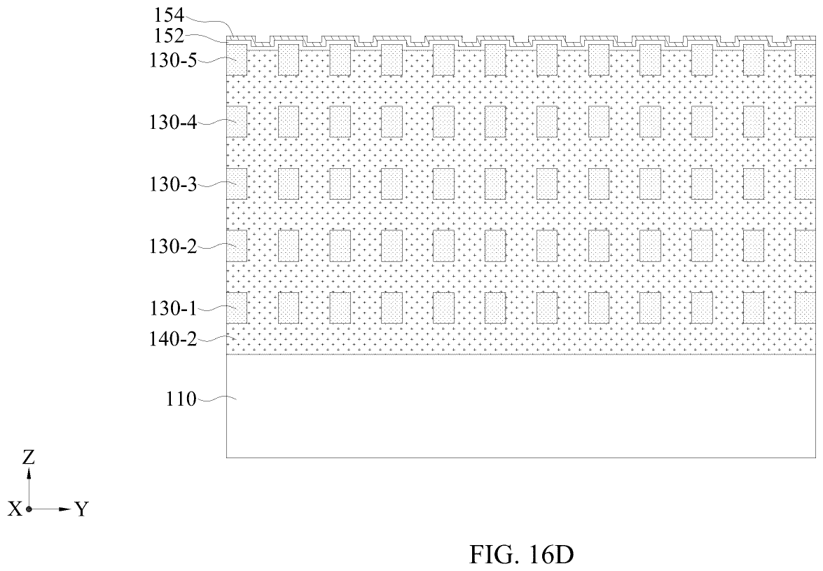

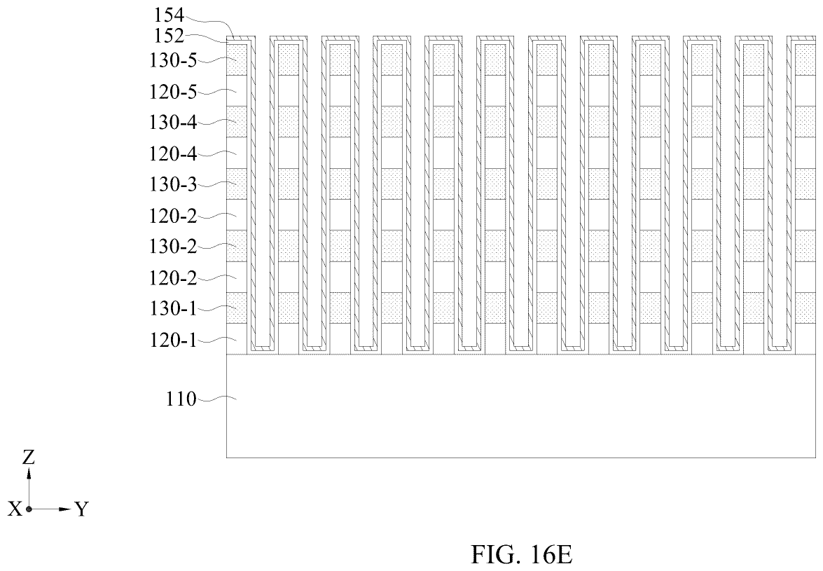

Referring to FIG. 16A, FIG. 16B, FIG. 16C, FIG. 16D, and FIG. 16E, a conductive layer 154 may be conformally formed on the capacitor dielectric 152. Capacitors 150-1, 150-2, 150-3, 150-4, 150-5, 150-6, 150-7, 150-8, 150-9, and 150-10 may be formed. In some embodiments, the conductive layer 154 may be formed on the array region 102. In some embodiments, the conductive layer 154 may be formed on the interconnection region 104. The conductive layer 154 may be formed by, for example, ALD, CVD, PVD, LPCVD, PECVD, or other suitable processes. In some embodiments, the conductive layer 154 may include a conductive material, such as titanium nitride or other suitable materials.

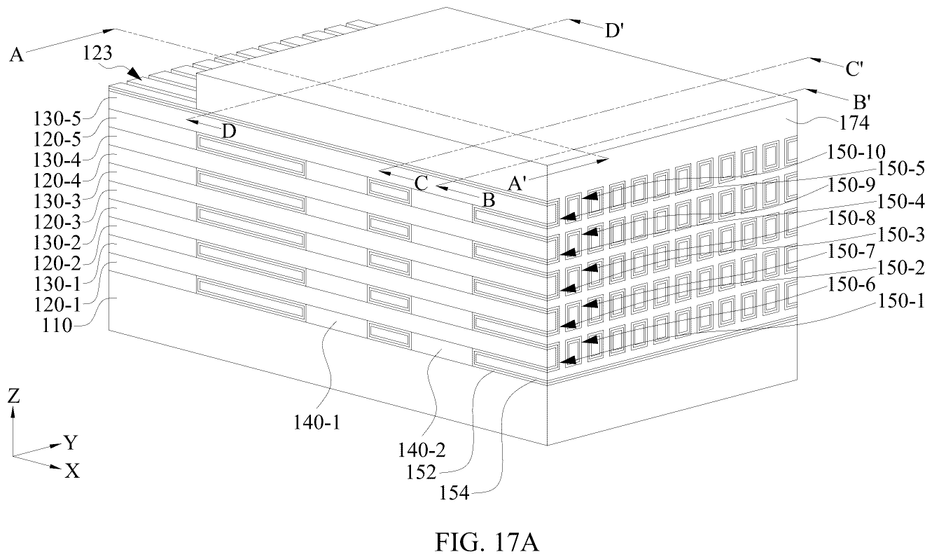

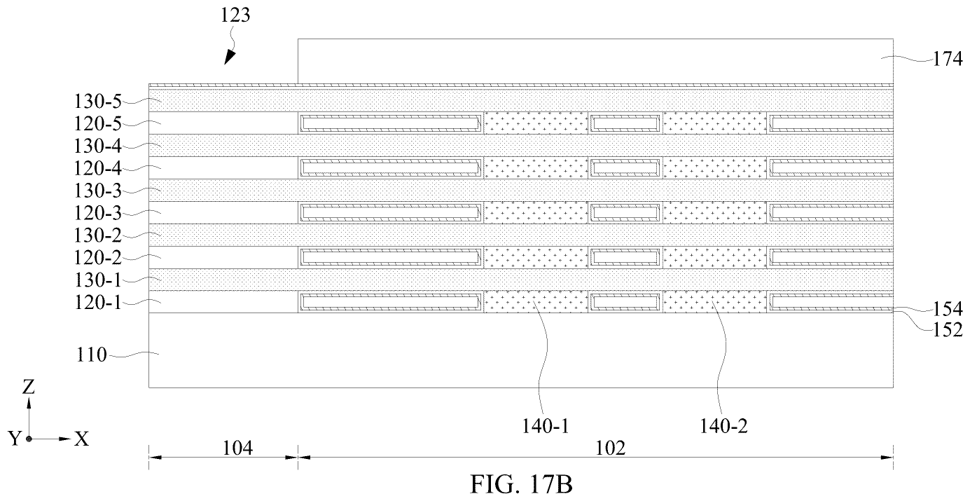

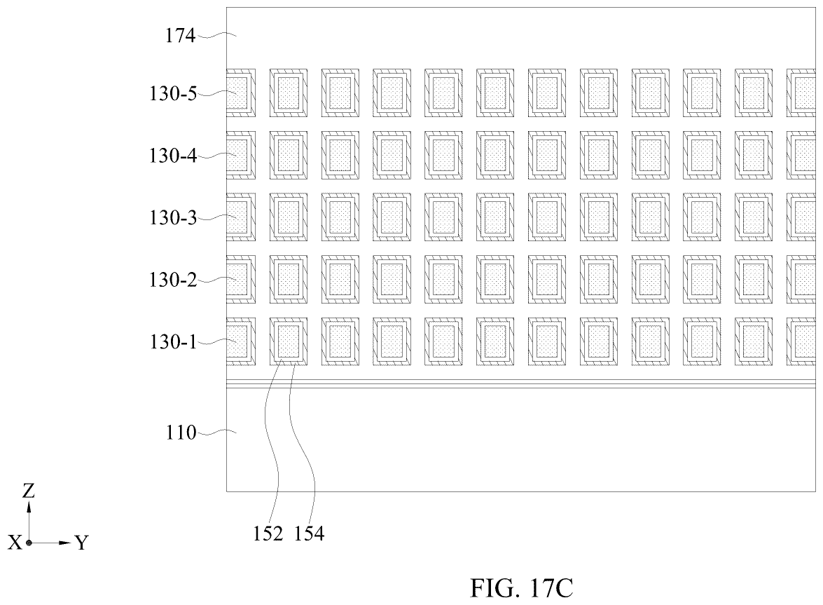

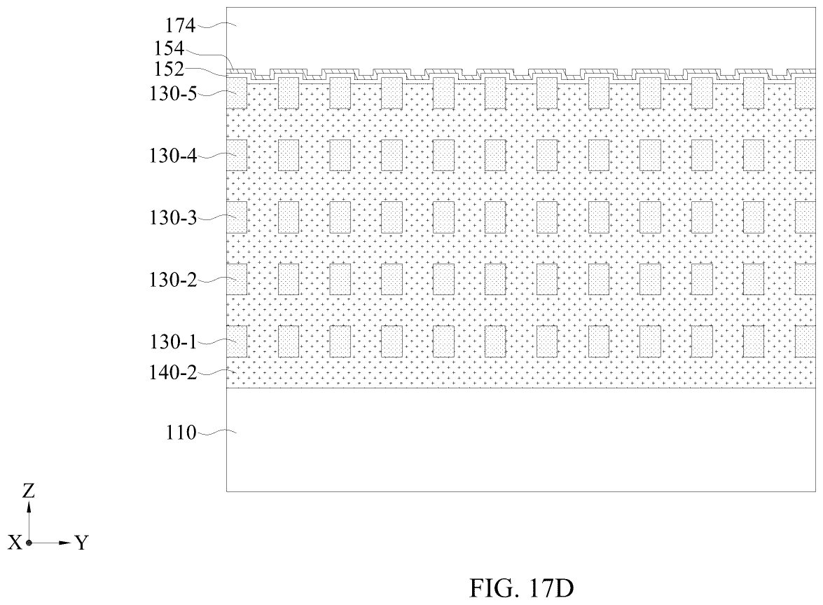

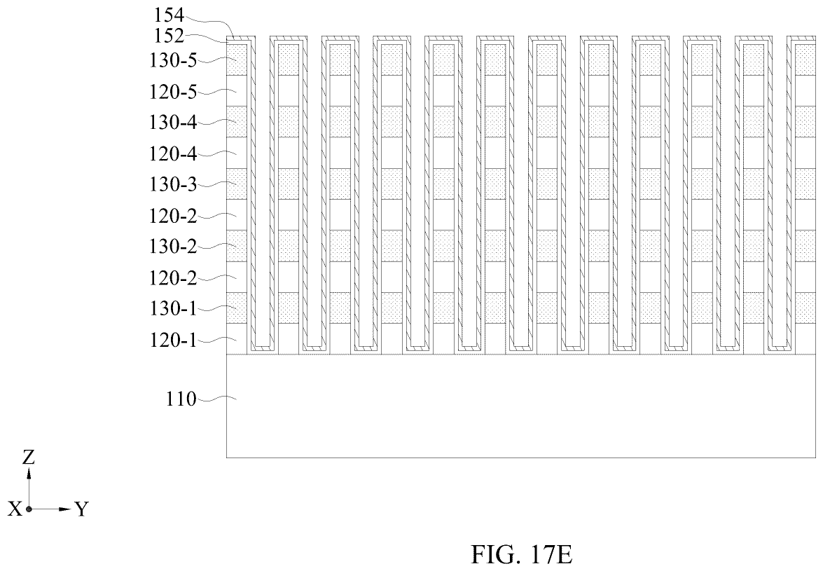

Referring to FIG. 17A, FIG. 17B, FIG. 17C, FIG. 17D, and FIG. 17E, a mask layer 174 may be formed to cover a portion 173 of the isolation layers 120-1, 120-2, 120-3, 120-4, and 120-5. The portion 173 of the isolation layers 120-1, 120-2, 120-3, 120-4, and 120-5 may correspond to the interconnection region 104. The mask layer 174 may include a negative-tone photoresist or a positive-tone photoresist. In some embodiments, the mask layer 174 may cover the array region 102. In some embodiments, the mask layer 174 may expose the interconnection region 104. The conductive layer 154 in the interconnection region 104 may be exposed by the mask layer 174.

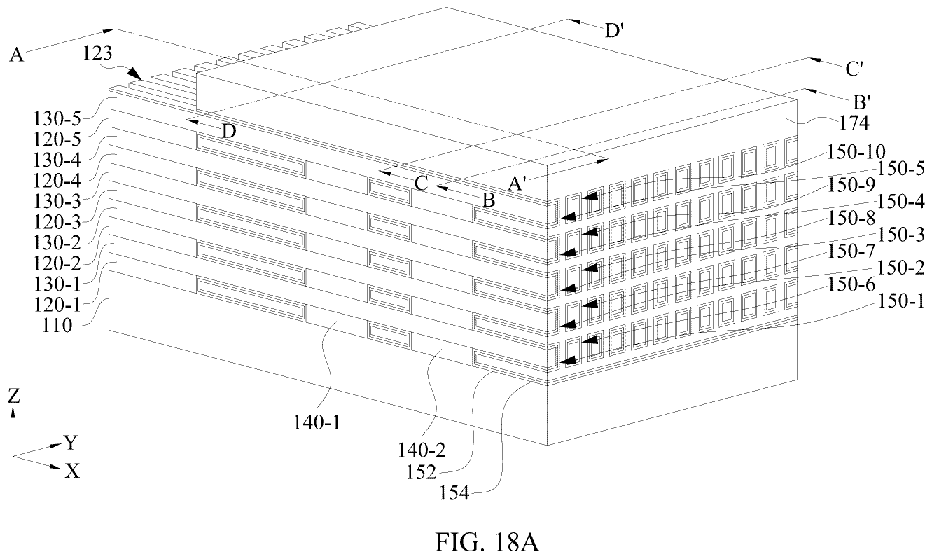

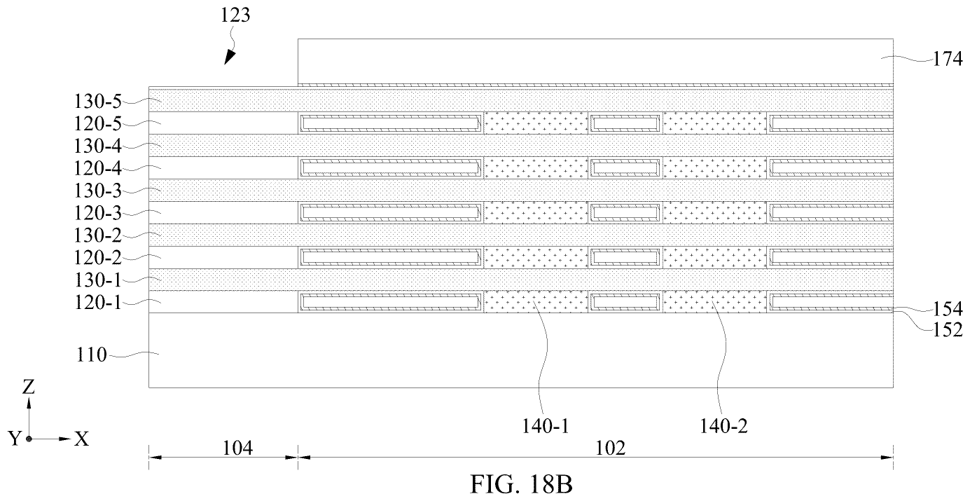

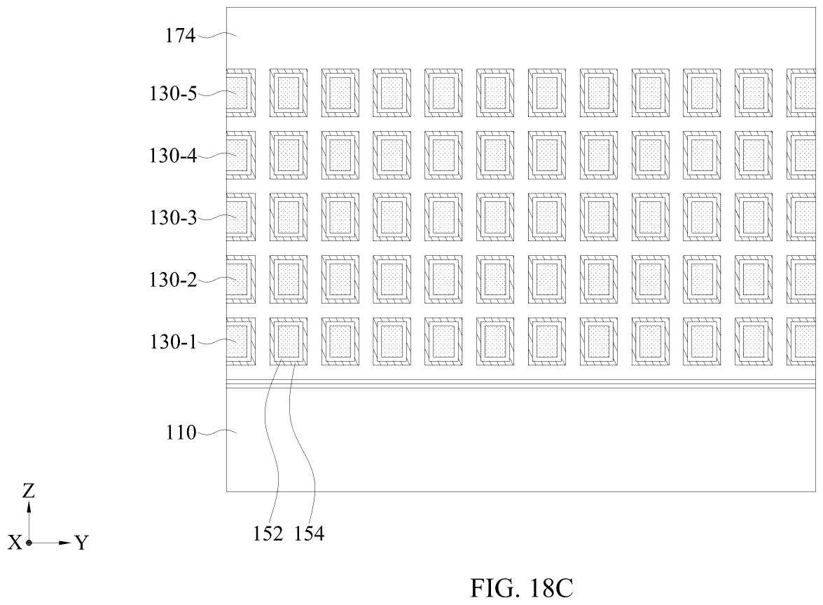

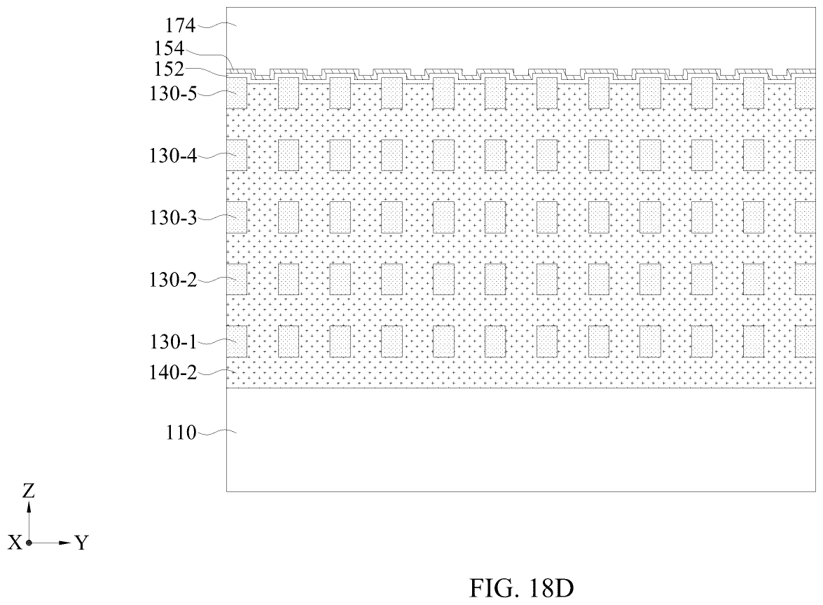

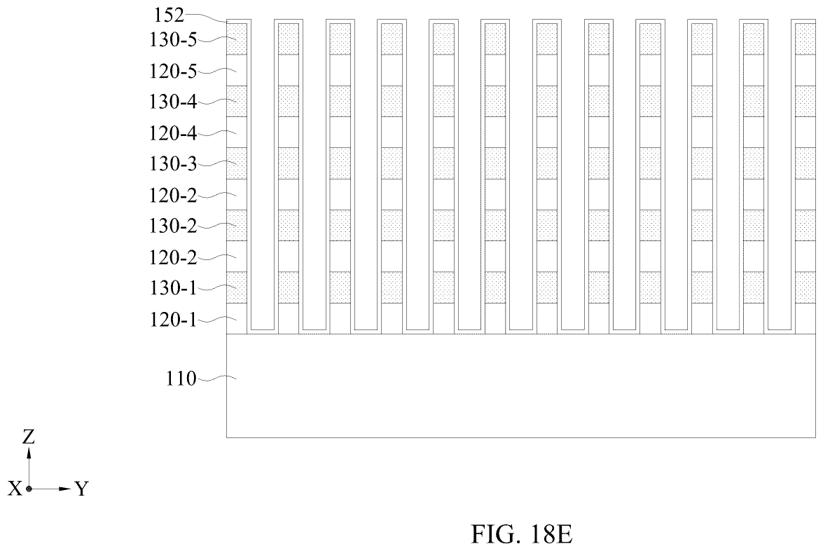

Referring to FIG. 18A, FIG. 18B, FIG. 18C, FIG. 18D, and FIG. 18E, the conductive layer 154 over the interconnection region 104 may be removed. The conductive layer 154 over the portion 123 of the isolation layers 120-1, 120-2, 120-3, 120-4, and 120-5 may be removed. The conductive layer 154 may be removed by, for example, a wet etching technique.

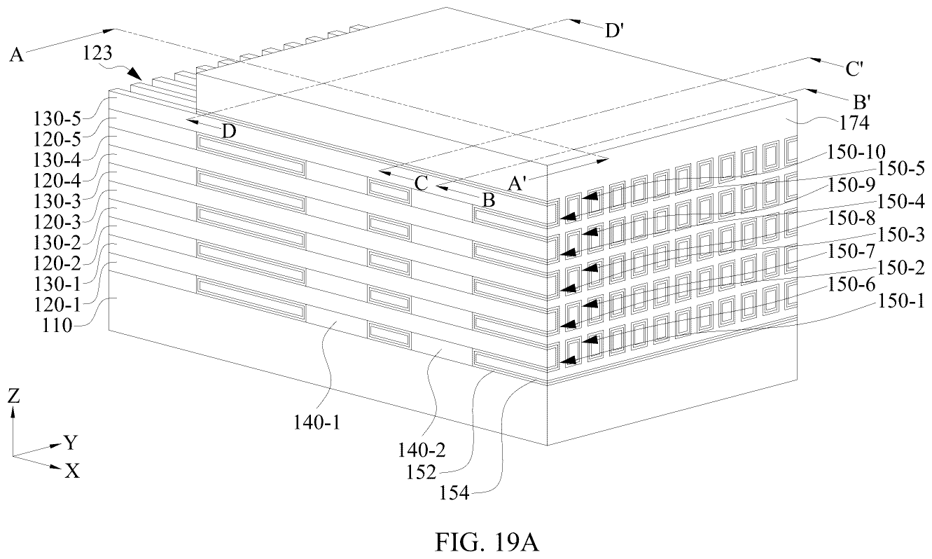

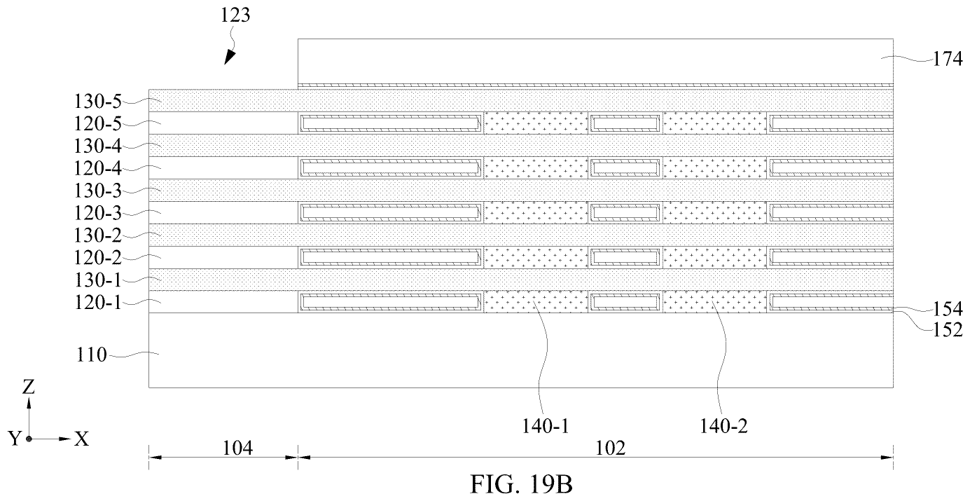

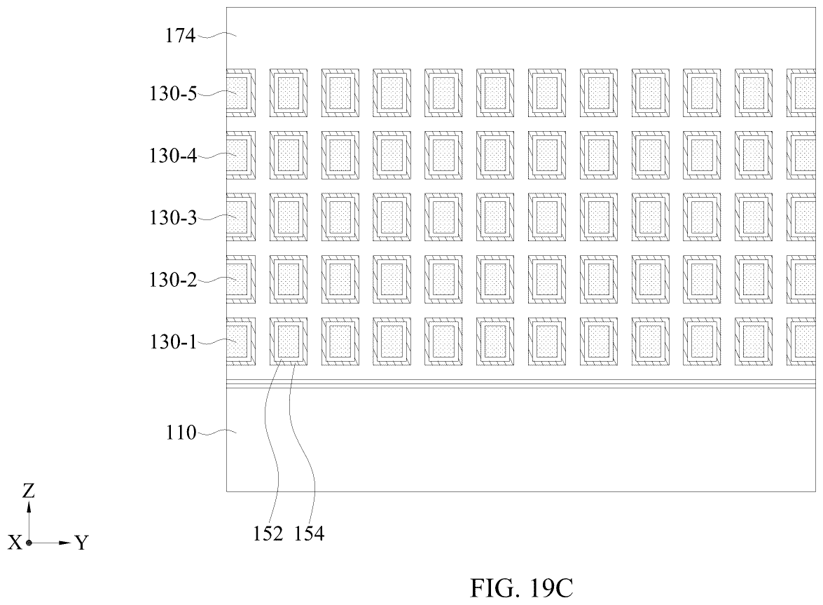

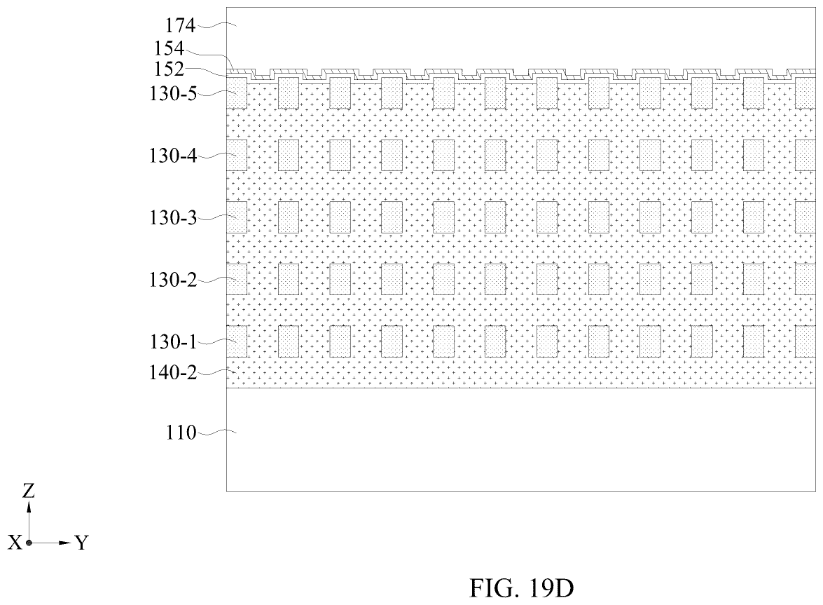

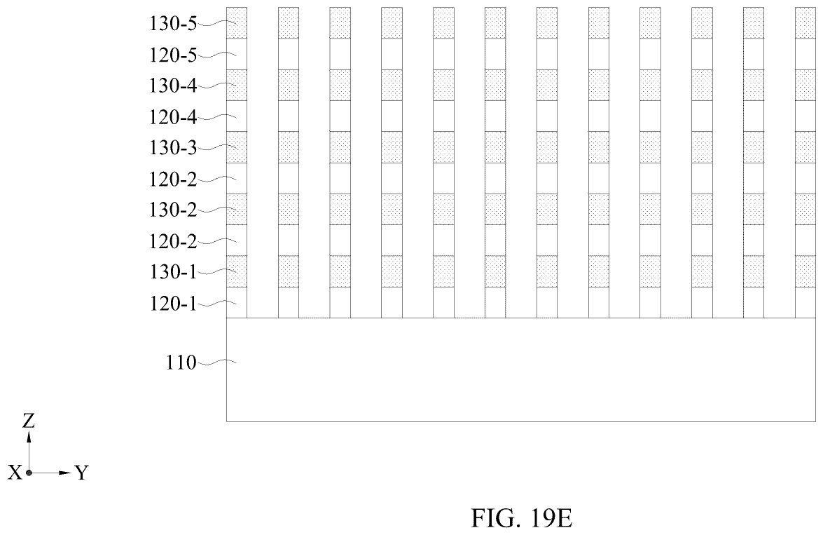

Referring to FIG. 19A, FIG. 19B, FIG. 19C, FIG. 19D, and FIG. 19E, the capacitor dielectric 152 over the interconnection region 104 may be removed. The capacitor dielectric 152 over the portion 123 of the isolation layers 120-1, 120-2, 120-3, 120-4, and 120-5 may be removed. The capacitor dielectric 152 may be removed by, for example, a wet etching technique.

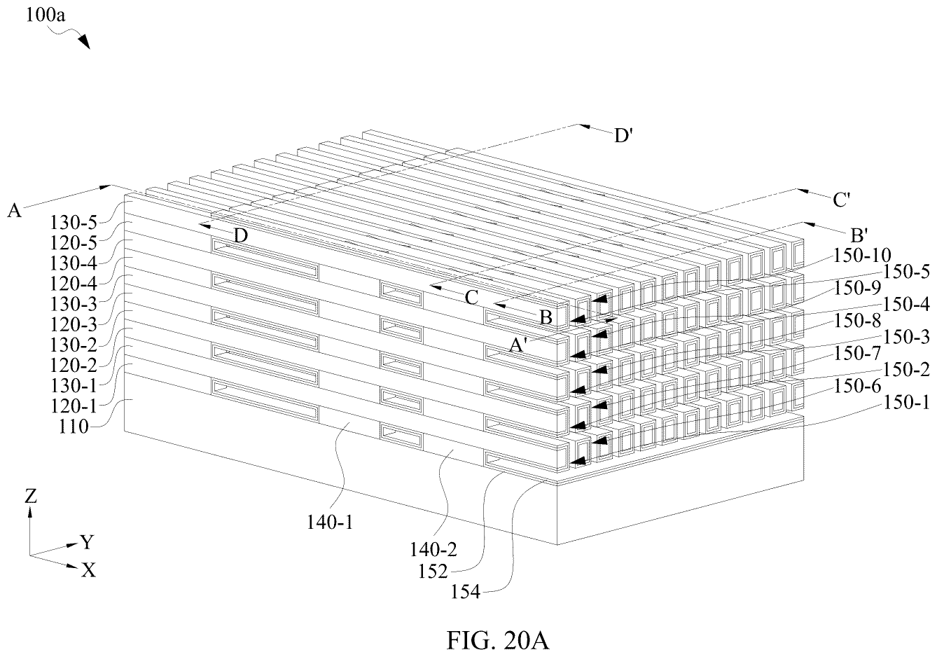

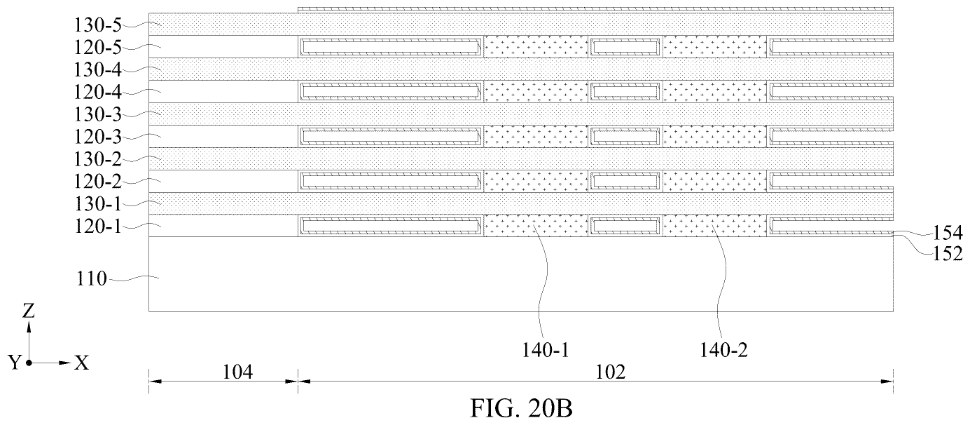

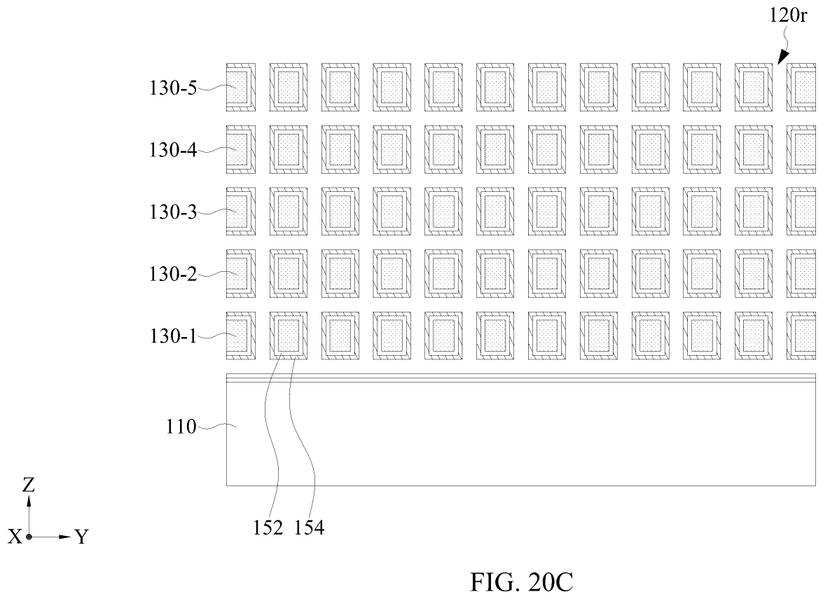

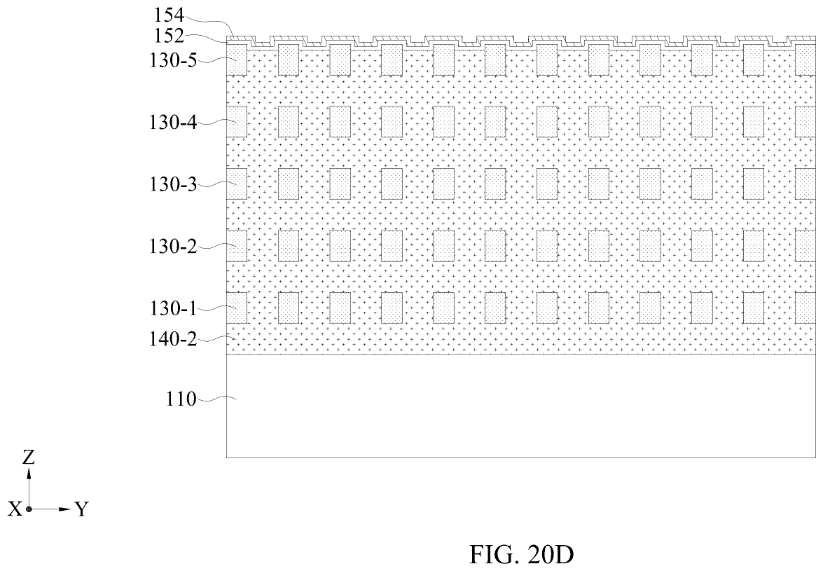

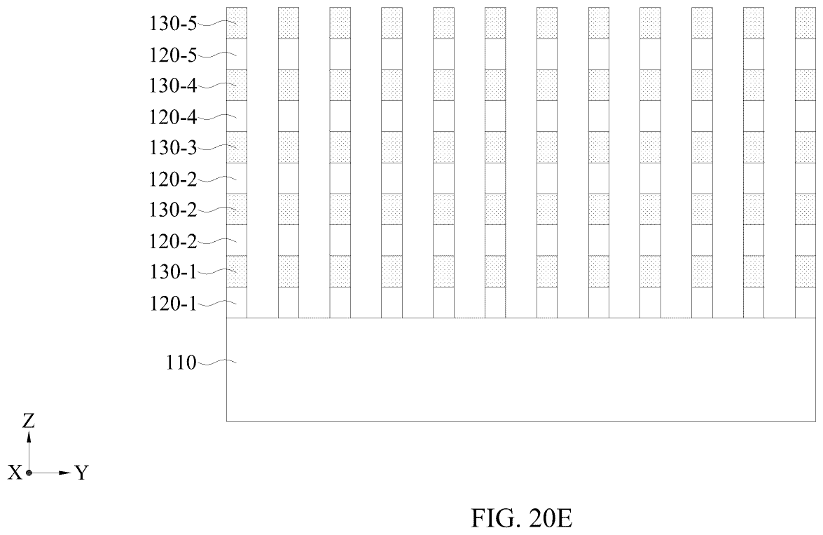

Referring to FIG. 20A, FIG. 20B, FIG. 20C, FIG. 20D, and FIG. 20E, the mask layer 174 may be removed. The conductive layers over the interconnection 104 of the 130-1, 130-2, 130-3, 130-4, and 130-5 may be exposed. The semiconductor device 100a may be produced.

One aspect of the present disclosure provides a semiconductor device. The semiconductor device includes a substrate, a plurality of capacitors, and a first supporting layer. The plurality of capacitors are disposed on the substrate. Each of the capacitors extends along a first direction. Each of the plurality of capacitors includes a first capacitor electrode, a second capacitor electrode, and a capacitor dielectric separating the first capacitor electrode from the second capacitor electrode. The first supporting layer is disposed on the substrate. The first supporting layer extends along a second direction different from the first direction. The capacitor dielectric includes a first surface and a second surface which are disposed on two opposite sides along the first direction. The second surface is exposed by the first capacitor electrode. The first supporting layer is disposed between the first surface and the second surface of the capacitor dielectric.

Another aspect of the present disclosure provides a semiconductor device. The semiconductor device includes a substrate and a plurality of capacitors. The substrate has an upper surface. The plurality of capacitors are disposed on the upper surface of the substrate. The plurality of capacitors are arranged along a plane that is substantially perpendicular to the upper surface of the substrate.

Another aspect of the present disclosure provides a method for manufacturing a semiconductor device. The method includes: providing a substrate; forming a plurality of isolation layers and a plurality of first conductive layers over the substrate, wherein the plurality of isolation layers and the plurality of first conductive layers are stacked alternatively; patterning the plurality of isolation layers and the plurality of first conductive layers to form a plurality of island structures; removing a first portion of the plurality of isolation layers to expose the plurality of first conductive layers; forming a capacitor dielectric to cover the plurality of first conductive layers; and forming a second conductive layers to cover the capacitor dielectric.

The embodiments of the present disclosure provide a semiconductor device. The semiconductor device may define a three-dimensional memory device. For example, the capacitors may be arranged along a plane which is substantially perpendicular to the upper surface of the substrate, which reduces the overall thickness of the semiconductor device. Further, the semiconductor device may include supporting layers. The supporting layers may be configured to reinforce the intermediate structure during manufacturing processes. The supporting layers may be configured to increase the length of the first capacitor electrode of the capacitor and prevent the first capacitor electrode from collapsing, which may increase the number of capacitors.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A method of manufacturing a semiconductor device, comprising:
providing a substrate;
forming a plurality of isolation layers and a plurality of first conductive layers over the substrate, wherein the plurality of isolation layers and the plurality of first conductive layers are stacked alternatively;
patterning the plurality of isolation layers and the plurality of first conductive layers to form a plurality of island structures;
removing a first portion of the plurality of isolation layers to expose the plurality of first conductive layers;
forming a capacitor dielectric to cover the plurality of first conductive layers; and
forming a second conductive layer to cover the capacitor dielectric.

2. The method of claim 1, further comprising:
forming a first mask layer to cover a second portion of the plurality of isolation layers before removing the first portion of the plurality of isolation layers, wherein the first mask layer exposes the first portion of the plurality of isolation layers; and
removing the first mask layer after removing the first portion of the plurality of isolation layers.

3. The method of claim 2, wherein the capacitor dielectric is formed on the second portion of the plurality of isolation layers, and the method comprises:
removing the capacitor dielectric over the second portion of the plurality of isolation layers.

4. The method of claim 2, wherein the second conductive layer is formed on the second portion of the plurality of isolation layers, and the method comprises:
removing the second conductive layer over the second portion of the plurality of isolation layers.

5. The method of claim 1, further comprising:
removing a third portion of the plurality of isolation layers to form an opening after forming the plurality of island structures; and
forming a supporting layer to fill the opening.

6. The method of claim 5, further comprising:
forming a second mask layer on the plurality of island structures, wherein the second mask layer exposes the third portion of the plurality of isolation layers before removing the third portion of the plurality of isolation layers;
forming a dielectric layer to fill the opening, wherein the dielectric layer is further formed on an upper surface of each of the plurality of island structures; and
removing the dielectric layer on the upper surface of each of the plurality of island structures.
